(19) United States
(12) Patent Application Publication
(10) Pub. No.: US 2010/0231761 A1
(43) Pub. Date: Sep. 16, 2010

(54) IMAGE SENSOR AND IMAGE CAPTURING APPARATUS

(75) Inventor: Toshikazu Yanai, Kawasaki-shi (JP)

Correspondence Address: COWAN LIEBOWITZ & LATMAN P.C.;JOHN J TORRENTE, 1133 AVE OF THE AMERICAS, NEW YORK, NY, 10036, US

(73) Assignee: CANON KABUSHIKI KAISHA, TOKYO (JP)

(21) Appl. No.: 12/717,474

(22) Filed: Mar. 4, 2010

(30) Foreign Application Priority Data
Mar. 16, 2009 (JP) 2009-063238

(51) Int. Cl. H04N 9/64; H04N 5/335

(52) U.S. Cl. 348/243; 348/300; 348/E05.091; 348/E05.079

(57) ABSTRACT

An image sensor having a pixel amplifier reduces noise generated by a driving transistor (Td1) by setting the gate width (channel width: W) and gate length (channel length: L) of the driving transistors (Td1) of light-shielded pixels arrayed in the first and second OB regions to be larger than those of photosensitive pixels arrayed in an effective pixel region. When the area of a photo-electric conversion element (D1) of a light-shielded pixel is reduced or light-shielded pixels having no photo-electric conversion unit are arrayed, the gate width (channel width: W) and gate length (channel length: L) can be further increased, further reducing noise.

### BACKGROUND OF THE INVENTION

1. Field of the Invention

The present invention relates to a noise reduction technique for a reference pixel for black level (OB pixel) in an image capturing apparatus.

2. Description of the Related Art

Today, advanced image sensors have significantly developed image capturing apparatuses such as an electronic still camera and video camera. An image sensor typified by a CMOS (Complementary Metal Oxide Semiconductor) includes a pixel array in which pixels are arrayed in the row and column directions. The image sensor is formed from an effective pixel region where photosensitive pixels are arranged and an OB region where reference pixels for black level (OB pixels) are shielded from light. An image capturing apparatus using the image sensor comprises an OB clamp circuit using OB pixels to remove the DC component of a dark current that greatly varies upon a change of conditions such as the temperature, and low-frequency variations upon power supply variations.

The clamp level (black level) of OB clamping can be vertical (V) OB or horizontal (H) OB in principle. However, this is so if a normal pixel output is output from the OB region regardless of the type of OB clamp circuit. If a so-called pixel defect exists in the OB region, information other than original OB pixel information is mixed in clamp information. The clamp circuit malfunctions, causing the image quality to deteriorate. Particularly when HOB clamping is employed, only the target line differs in clamping (clamp error) from preceding and succeeding lines. The signal level difference stands out as noise in the form of a horizontal streak. The presence of even a small defect results in poor image quality.

Noise generated in an OB pixel also generates horizontal streak noise. It is necessary to perform HOB clamping using as many OB pixels as possible. For this purpose, the following methods have been proposed.

Japanese Patent Laid-Open No. 2001-268448 proposes a technique of setting a stricter defect determination level in the OB region than that in the normal effective pixel region for a pixel defect in an image sensor. This method can prevent deterioration of the image quality in OB clamping caused by an OB pixel defect. However, this method decreases the yield of the image sensor and raises the cost because the defect determination level in the OB region is set stricter than that in the normal effective pixel region.

According to a technique disclosed in Japanese Patent Laid-Open No. 2002-064196, stable HOB clamping is done with the second OB pixels free from a pixel defect generated in a photo-electric conversion unit in an image sensor in which the OB region is formed from the first OB pixels having photo-electric conversion units and the second OB pixels having no photo-electric conversion unit. A signal processing circuit uses the average value of the first OB pixels, thereby removing the DC component of a dark current.

Japanese Patent Laid-Open No. 2003-134400 discloses an application of the same arrangement as that of the OB region in Japanese Patent Laid-Open No. 2002-064196 to a CMOS image sensor.

An image capturing apparatus using a CMOS image sensor includes a noise removal circuit formed from a sample-and-hold circuit and a switching transistor for each vertical signal line, in order to remove pixel nonuniformity arising from variations in the threshold of the amplification transistor of a pixel amplifier arranged in each pixel.

However, variations in the threshold of the transistor of a circuit arranged on each vertical signal line generate noise that differs between columns. The noise appears as vertical streak noise on a reproduced image. To remove the vertical streak noise, the following methods have been proposed.

According to techniques disclosed in Japanese Patent Laid-Open Nos. 2000-261730 and 2006-025146, a correction signal for one line is generated by adding a plurality of OB line signals read out from the VOB region for each column. The correction signal is subtracted from an effective pixel line signal from an effective pixel region, thereby removing vertical streak noise.

According to a technique disclosed in Japanese Patent Laid-Open No. 10-126697, immediately before reading out a signal from the OB line of the VOB region, OB pixels are reset for each line, obtaining an OB line signal free from a pixel defect.

A method described in Japanese Patent Laid-Open No. 2005-223860 removes vertical streak noise using an image sensor having a VOB region formed from OB pixels having photo-electric conversion units and OB pixels having no photo-electric conversion unit, as shown in FIG. 12 of this reference. According to a method proposed in Japanese Patent Laid-Open No. 2005-223860, an amplification transistor, which is larger in size than the amplification transistor of an amplifier within a pixel, is arranged in an amplifier outside a pixel for each vertical signal line, instead of an OB pixel having no photo-electric conversion unit. This method can remove vertical streak noise by only one line.

Recent progresses in megapixel structures and semiconductor micropatterning techniques promote reduction of the pixel areas of image sensors. Along with this, elements included in a pixel are also shrinking in size. A case in which the amplification transistor of a pixel amplifier, which is a MOS transistor for amplifying a signal corresponding to charges generated in a photo-electric conversion unit, is miniaturized will be examined.

Letting W be the gate width of the amplification transistor, L be its gate length, and Cox be the gate insulating film capacitance per unit area, it is known that noise generated in the amplification transistor is inversely proportional to the square root of (W×L×Cox). More specifically, as the amplification transistor is miniaturized to decrease the gate width or gate length, noise generated in the amplification transistor increases. Even in an image sensor using a CMOS image sensor, a smaller pixel area increases noise generated in the amplification transistors of pixel amplifiers in the effective pixel region and OB region, as described above.

In Japanese Patent Laid-Open Nos. 2002-064196 and 2003-134400, the clamp operation is executed using a reference signal for black level read out from the HOB region. If the amount of noise that is generated in the amplification transistor of a pixel amplifier and contained in a reference pixel for black level increases, the clamp precision decreases, deteriorating the image quality.

In Japanese Patent Laid-Open Nos. 2000-261730, 2006-025146, and 10-126697, and FIG. 12 of Japanese Patent Laid-Open No. 2005-223860, vertical streak noise in a signal read out from the effective pixel region is corrected using a reference signal for black level read out from the VOB region. Hence, if the amount of noise which is generated in the amplification transistor of a pixel amplifier and contained in a reference pixel for black level increases, the correction precision decreases, deteriorating the image quality.

In Japanese Patent Laid-Open No. 2005-223860, because the amplification transistor of a pixel amplifier operates differently from a pixel, the same signal as that containing vertical streak noise generated in a pixel cannot be obtained, impeding accurate correction.

### SUMMARY OF THE INVENTION

The present invention has been made to overcome the conventional drawbacks, and implements a technique to reduce noise contained in a reference signal for black level read out from a reference pixel for black level.

According to the first aspect of the present invention, there is provided an image sensor comprising: an effective pixel having a photo-electric conversion unit for converting an optical signal into charges, a charge-voltage conversion unit for converting a charge into a voltage, and a pixel amplifier for amplifying a voltage of the charge-voltage conversion unit; and a reference pixel for black level which has a charge-voltage conversion unit and a pixel amplifier and is shielded from light, wherein each of the pixel amplifier of the effective pixel and the pixel amplifier of the reference pixel for black level has at least one transistor which is connected to the corresponding charge-voltage conversion unit to form a source follower circuit, and the effective pixel and the reference pixel for black level are different in at least one of a gate width and gate length of the transistor of the pixel amplifier.

According to the second aspect of the present invention, there is provided an image capturing apparatus comprising: an image sensor including an effective pixel having a photo-electric conversion unit for converting an optical signal into charges, a charge-voltage conversion unit for converting a charge into a voltage, and a pixel amplifier for amplifying a voltage of the charge-voltage conversion unit, and a reference pixel for black level which has a charge-voltage conversion unit and a pixel amplifier and is shielded from light; and a correction circuit which corrects an image signal output from the effective pixel by using a reference signal for black level output from the reference pixel for black level, wherein each of the pixel amplifier of the effective pixel and the pixel amplifier of the reference pixel for black level has at least one transistor which is connected to the corresponding charge-voltage conversion unit to form a source follower circuit, and the effective pixel and the reference pixel for black level are different in at least one of a gate width and gate length of the transistor of the pixel amplifier.

Further features of the present invention will become apparent from the following description of exemplary embodiments with reference to the attached drawings.

### BRIEF DESCRIPTION OF THE DRAWINGS

FIG. 1 is a block diagram showing the arrangement of an image capturing apparatus according to an embodiment of the present invention;

FIG. 2 is a diagram showing the detailed arrangement of an image sensor in FIG. 1;

FIG. 3 is a circuit diagram showing the detailed structure of the photosensitive pixel of the image sensor;

FIG. 4 is a circuit diagram showing the detailed arrangement of the sample-and-hold circuit of the image sensor;

FIG. 5 is a view showing the pixel array of the image sensor;

FIG. 6 is a view showing the layout of the photosensitive pixel of the image sensor;

FIG. 7 is a sectional view showing the section of the pixel of the image sensor;

FIG. 8 is a circuit diagram showing the detailed structure of the light-shielded pixel of the image sensor;

FIG. 9 is a view showing the layout of the light-shielded pixel of the image sensor;

FIG. 10 is a view showing the layout of the light-shielded pixel of the image sensor;

FIG. 11 is a circuit diagram showing the detailed structure of the light-shielded pixel of the image sensor;

FIG. 12 is a view showing the layout of the light-shielded pixel of the image sensor;

FIG. 13 is a view showing the layout of the light-shielded pixel of the image sensor;

FIG. 14 is a view showing the pixel array of the image sensor;

FIG. 15 is a view showing the pixel array of the image sensor;

FIG. 16 is a view showing the pixel array of the image sensor;

FIG. 17 is a view showing the pixel array of the image sensor;

FIG. 18 is a view showing the pixel array of the image sensor;

FIG. 19 is a view showing the pixel array of the image sensor;

FIG. 20 is a view showing the pixel array of the image sensor;

FIG. 21 is a view showing the pixel array of the image sensor;

FIG. 22 is a view showing the layout of the light-shielded pixel of the image sensor;

FIG. 23 is a view showing the layout of the light-shielded pixel of the image sensor;

FIG. 24 is a view showing the layout of the light-shielded pixel of the image sensor;

FIG. 25 is a view showing the layout of the light-shielded pixel of the image sensor;

FIG. 26 is a view showing the layout of the light-shielded pixel of the image sensor;

FIG. 27 is a view showing the layout of the light-shielded pixel of the image sensor;

FIG. 28 is a view showing the layout of the light-shielded pixel of the image sensor; and

FIG. 29 is a view showing the layout of the light-shielded pixel of the image sensor.

### DESCRIPTION OF THE EMBODIMENTS

Embodiments of the present invention will be described in detail below with reference to the accompanying drawings. The embodiments set forth are merely examples of a means for implementing the present invention and should be properly corrected or modified depending on the arrangement of an apparatus to which the present invention is applied, and various conditions. The present invention is not limited to the following embodiments.

An image capturing apparatus according to the present invention is implemented by an electronic still camera or video camera with a movie function. The image capturing apparatus includes a megapixel image sensor, an image display unit capable of displaying an image sensed by the image sensor, and an image recording unit capable of recording an image. The image capturing apparatus is premised on that a pixel count used to display and record a movie is smaller than that used to record a still image.

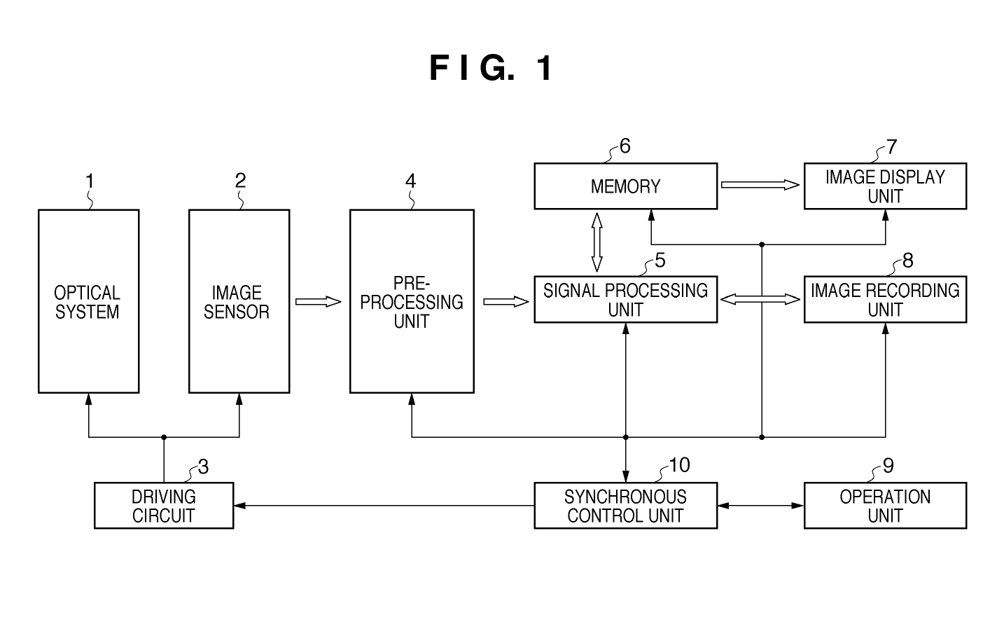

FIG. 1 is a block diagram showing the arrangement of an image capturing apparatus according to an embodiment of the present invention.

Referring to FIG. 1, the image capturing apparatus according to the embodiment of the present invention includes an optical system 1, an image sensor 2, a driving circuit 3, a pre-processing unit 4, a signal processing unit 5, a memory 6 for storing image data, an image display unit 7, an image recording unit 8, an operation unit 9, and a synchronous control unit 10.

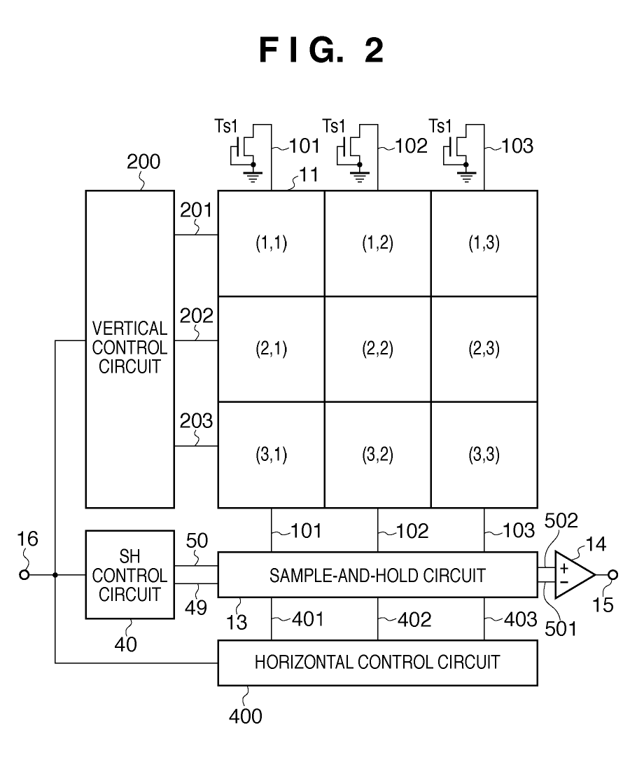

The optical system 1 includes a focusing lens for forming an object image on the image sensor 2, a zoom lens for optically zooming, a stop for adjusting the brightness of an object image, and a shutter for controlling exposure. The driving circuit 3 drives these components. The image sensor 2 includes a plurality of pixels arrayed in a matrix, and a circuit for outputting signals read out from these pixels in a predetermined order. Details of the image sensor 2 will be described later with reference to FIG. 2.

In response to a control signal from the synchronous control unit 10, the driving circuit 3 drives the optical system 1 and image sensor 2 by supplying a constant voltage and a pulse with enhanced driving performance. The driving circuit 3 also has a function of transmitting a control signal from the synchronous control unit 10 to the image sensor 2.

The pre-processing unit 4 is controlled by a control signal from the synchronous control unit 10. The pre-processing unit 4 includes a correlated double sampling circuit (CDS circuit) for removing a noise component such as reset noise from an analog signal output from the image sensor 2. The pre-processing unit 4 further includes a gain control amplifier for adjusting the amplitude of a noise-free signal, and an A/D converter for converting an amplitude-adjusted analog signal into a digital signal.

In the embodiment of the present invention, the pre-processing unit 4 performs a clamp operation using reference signals for black level read out from the VOB region and HOB region (clamp circuit). If not necessary, VOB clamping need not be executed. A concrete clamp operation is the same as a description of FIG. 2 in Japanese Patent Laid-Open No. 2001-268448 and a description of FIG. 2 in Japanese Patent Laid-Open No. 2002-064196. A description of the concrete clamp operation will be omitted.

The signal processing unit 5 is controlled by a control signal from the synchronous control unit 10. The signal processing unit 5 performs appropriate signal processing for an output signal which has been converted into a digital signal and sent from the pre-processing unit 4, and converts the processed signal into image data. The signal processing unit 5 outputs an output signal converted into a digital signal and image data to the memory 6 and image recording unit 8. The signal processing unit 5 executes signal processing upon receiving an output signal converted into a digital signal and image data from the memory 6 and image recording unit 8. The signal processing unit 5 also has a function of detecting photometric data such as a focusing state and exposure from a signal output from the image sensor 2, and sending the data to the synchronous control unit 10.

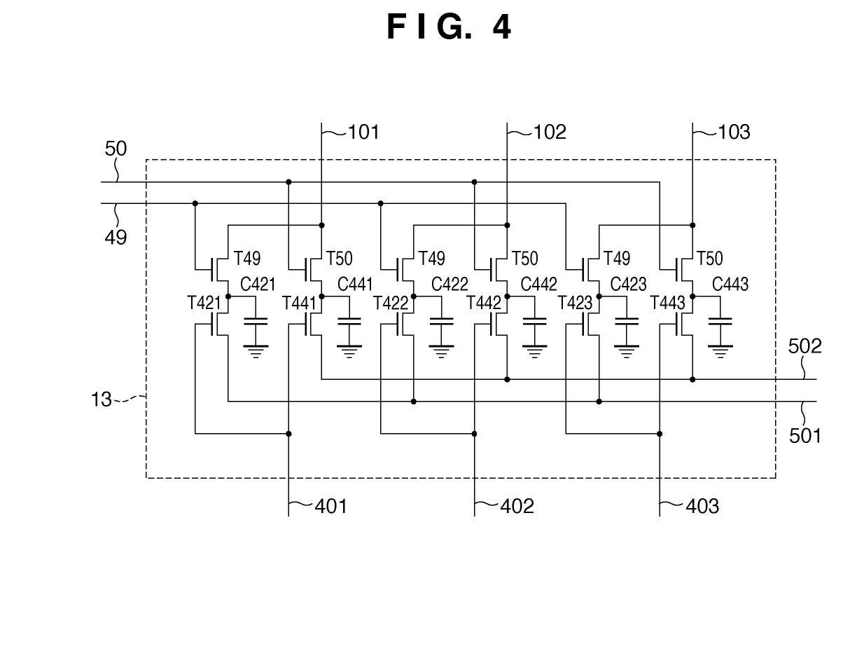

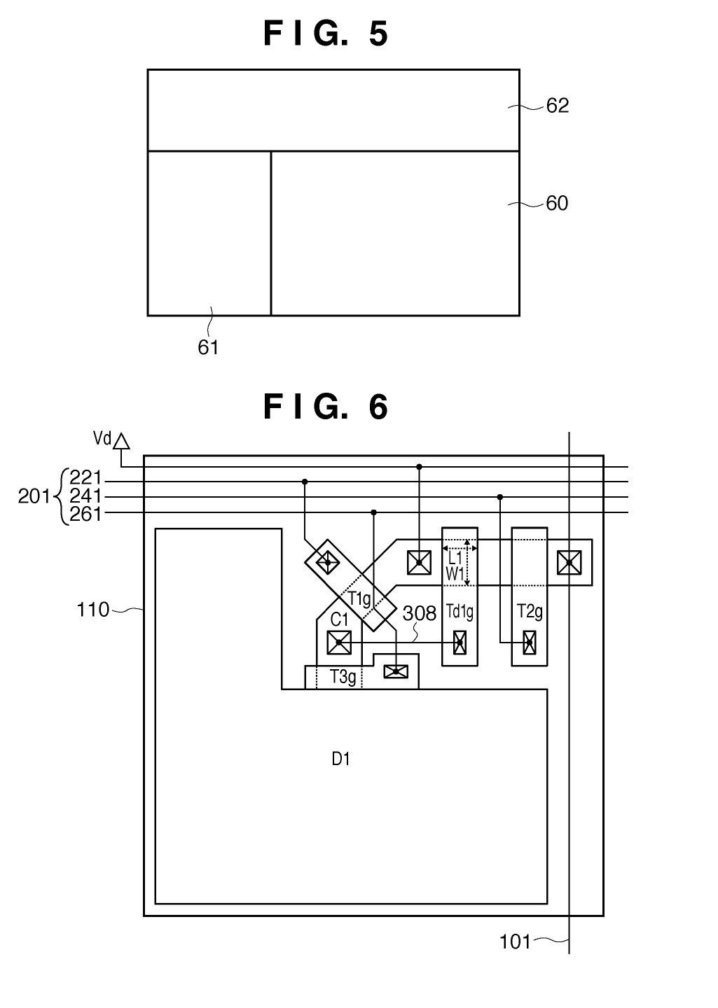

In the embodiment of the present invention, the signal processing unit 5 includes a correction circuit for performing a vertical streak noise correction operation. In the vertical streak noise correction operation, a correction signal for one line is generated from reference signals for black level read out from the VOB region. The correction signal is subtracted from a signal output from the image sensor. A concrete correction operation is the same as a description of FIG. 4 in Japanese Patent Laid-Open No. 2000-261730 and a description of FIGS. 4 and 5 in Japanese Patent Laid-Open No. 2006-025146. A description of the concrete correction operation will be omitted.

In the embodiment of the present invention, the signal processing unit 5 performs a digital clamp operation using reference signals for black level read out from the HOB region. In the digital clamp operation, reference signals for black level are averaged. The average signal is subtracted from a signal output from the image sensor. A concrete clamp operation is the same as a description of FIG. 2 in Japanese Patent Laid-Open No. 2002-064196. A description of the concrete clamp operation will be omitted.

The memory 6 is controlled by a control signal from the synchronous control unit 10. The memory 6 temporarily stores a signal which has been output from the image sensor 2 and converted into a digital signal, and image data having undergone signal processing. The memory 6 also has a function of outputting display image data to the image display unit 7.

The image display unit 7 is controlled by a control signal from the synchronous control unit 10. The image display unit 7 displays display image data to be stored in the memory 6, in order to allow the user to decide the composition before shooting or confirm a shot image. The image display unit 7 is formed from an electronic viewfinder (EVF) and liquid crystal display (LCD). In general, the image display unit 7 has a display pixel count smaller than the vertical pixel count of the image sensor 2. In the embodiment, the display pixel count of the image display unit 7 is smaller than the output pixel count of the image sensor 2.

The image recording unit 8 includes a detachable memory and the like, and is controlled by a control signal from the synchronous control unit 10. The image recording unit 8 can record an output signal converted into a digital signal and image data which are sent from the signal processing unit 5, and read image data from the detachable memory.

The operation unit 9 notifies the synchronous control unit 10 of an external instruction using operation members such as a switch, push button, lever, and dial. Examples of the external instruction are the state of the power switch of the image capturing apparatus, that of the push button for designating shooting, that of the button or lever for designating the optical zoom or electronic zoom, and that of the mode dial for selecting a shooting mode. The operation unit 9 notifies the synchronous control unit 10 of an image display instruction before shooting, various shooting instructions, and a menu operation to designate display of a shot image or the operation of the image capturing apparatus in advance. In response to a control signal from the synchronous control unit 10, the operation unit 9 can display the state of the image capturing apparatus on a display (e.g., an LCD or LED) or the image display unit 7. It is also possible to use the image display unit 7 as a display and a touch panel attached to the image display unit 7 as an operation member, and perform an on-screen operation.

The synchronous control unit 10 controls the overall image capturing apparatus based on an instruction from the operation unit 9. The synchronous control unit 10 controls the optical system 1 to form an optimum object image on the image sensor 2 in accordance with photometric data such as a focusing state and exposure sent from the signal processing unit 5. The synchronous control unit 10 can detect the use status of the memory 6 and the attachment/detachment and use status of the memory of the image recording unit 8.

Main operations of the image capturing apparatus according to the embodiment of the present invention will be explained.

### Control of Display Image

(1) The image capturing apparatus is turned on in response to an instruction from the power switch of the operation unit 9.

(2) The signal processing unit 5 converts an image signal from the image sensor 2 into display image data, and displays the image data on the image display unit 7. Also, the signal processing unit 5 detects photometric data and sends it to the synchronous control unit 10.

(3) The synchronous control unit 10 controls the optical system 1 based on the photometric data.

(4) The image capturing apparatus repeats (2) and (3), and waits for an instruction from the operation unit 9.

### Control of Still Image Shooting

(1) Control of still image shooting starts in response to an instruction from the shooting switch of the operation unit 9.

(2) The signal processing unit 5 detects photometric data from an image signal from the image sensor 2, and sends it to the synchronous control unit 10.

(3) The synchronous control unit 10 controls the optical system 1 based on the photometric data.

(4) The image sensor 2 is exposed for still image recording and outputs a signal.

(5) The signal processing unit 5 converts an image signal from the image sensor 2 into recording image data, and sends the image data to the image recording unit 8 to record it on a detachable memory. In addition, the signal processing unit 5 converts the image signal into display image data and displays the image data on the image display unit 7.

(6) The image capturing apparatus returns to (4) of <Control of Display Image>.

### Control of Movie Shooting

(1) Control of movie shooting starts in response to an instruction from the shooting switch of the operation unit 9.

(2) The signal processing unit 5 converts an image signal from the image sensor 2 into recording image data, and sends the image data to the image recording unit 8 to record it on a detachable memory. At the same time, the signal processing unit 5 converts the image signal into display image data and displays the image data on the image display unit 7.

(3) The signal processing unit 5 detects photometric data from an image signal from the image sensor 2, and sends it to the synchronous control unit 10.

(4) The synchronous control unit 10 controls the optical system 1 based on the photometric data. The image sensor 2 is exposed for movie recording and outputs a signal.

(5) The image capturing apparatus repeats (2) to (4), and waits for an instruction from the operation unit 9.

The image sensor 2 will be explained with reference to FIGS. 2 to 4. In FIG. 2, the pixel count of the image sensor 2 is three in both the horizontal and vertical directions for descriptive convenience.

Referring to FIG. 2, a pixel 11 is a pixel (photosensitive pixel) for converting incident light (optical signal) into an electrical signal. (1,1) is an address indicating horizontal (H) and vertical (V) pixel positions. The remaining pixels have the same structure as that of the pixel 11 except that corresponding vertical control lines and vertical signal lines differ between the pixels. (H,V) is an address indicating a pixel position.

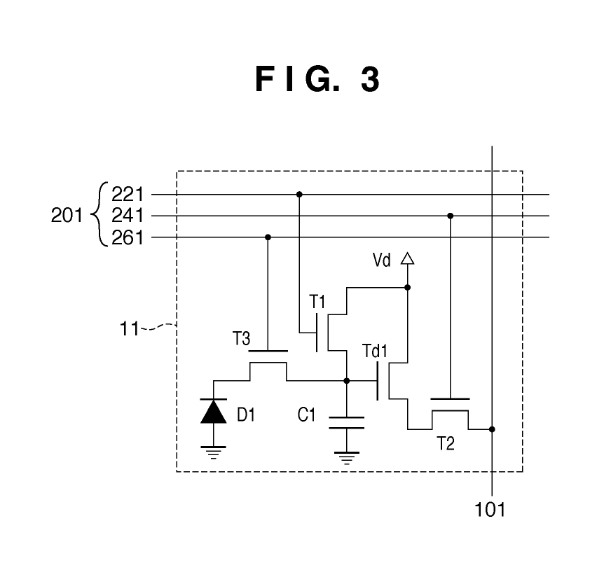

FIG. 3 exemplifies the structure of the pixel 11. In FIG. 3, a portion surrounded by a dotted line is the pixel 11. The pixel 11 is connected to other circuits via a vertical control line 201 and vertical signal line 101. The vertical control line 201 is commonly connected to pixels on one horizontal row and can simultaneously control them. The vertical signal line 101 is commonly connected to pixels on one vertical column and outputs signals from them. The vertical control line 201 includes a reset control line 221, vertical address line 241, and transfer control line 261.

A photo-electric conversion element D1 (photo-electric conversion unit) converts light into charges. An FD capacitor C1 (charge-voltage conversion unit) accumulates charges when converting charges of the photo-electric conversion element D1 into a voltage. A driving transistor (amplification unit) Td1 is a transistor for driving a pixel amplifier, and outputs a voltage corresponding to the voltage of the FD capacitor C1. A reset transistor (reset switch) T1 is connected to the reset control line 221 to reset the voltage of the FD capacitor C1.

A selection transistor (selection switch) T2 is connected to the vertical address line 241 to output an output from the driving transistor Td1 as the output signal of the pixel to the vertical signal line 101. A transfer transistor (transfer switch) T3 is connected to the transfer control line 261 to control transfer of charges from the photo-electric conversion element D1 to the FD capacitor C1. A power supply Vd is used for the driving transistor Td1 and reset transistor T1.

In the embodiment of the present invention, transistors other than the driving transistor Td1 function as switches, and are turned on upon activating the control line connected to their gates and off upon inactivating it.

Noise readout and pixel signal readout in the image sensor 2 will be described.

Noise readout when reading out signals from pixels on one horizontal row of the image sensor 2 will be explained first. The vertical control line controls all pixels on one horizontal row. The pixel (1,1) will be exemplified, but the remaining pixels operate similarly.

While the transfer transistor T3 is OFF, the reset transistor T1 is turned on via the reset control line 221 to reset the voltage of the FD capacitor C1, and then turned off. The selection transistor T2 is turned on via the vertical address line 241 to output the reset voltage of the FD capacitor C1 to the vertical signal line (signal output line) 101. This signal serves as a noise signal, and the noise signal readout operation is defined as noise readout. If necessary, the selection transistor T2 is turned off via the vertical address line 241.

Next, pixel signal readout will be explained. While the reset transistor T1 is OFF, the transfer transistor T3 is turned on via the transfer control line 261 to transfer charges from the photo-electric conversion element D1 to the FD capacitor C1. A noise signal generated in the FD capacitor C1 and the charges transferred from the photo-electric conversion element D1 are added to convert the charges into the voltage of a pixel signal. After that, the selection transistor T2 is turned on via the vertical address line 241 to output the signal voltage of the FD capacitor C1 to the vertical signal line 101. This signal serves as a pixel signal, and the pixel signal readout operation is defined as pixel signal readout. If necessary, the selection transistor T2 is turned off via the vertical address line 241.

In this description, noise readout and pixel signal readout are defined separately. However, a series of operations from noise readout to pixel signal readout may be defined as continuous signal readout as follows. In continuous signal readout, noise readout is done first. When reading out signals from pixels on one horizontal row of the image sensor 2, while the transfer transistor T3 is OFF, the reset transistor T1 is turned on via the reset control line 221 to reset the voltage of the FD capacitor C1, and then turned off. The selection transistor T2 is turned on via the vertical address line 241 to output the reset voltage of the FD capacitor C1 to the vertical signal line 101. This signal serves as a noise signal. In this state, the reset transistor T1 is OFF, so pixel signal readout is performed successively.

The transfer transistor T3 is turned on via the transfer control line 261 to transfer charges from the photo-electric conversion element D1 to the FD capacitor C1. The noise signal generated in the FD capacitor C1 and the charges transferred from the photo-electric conversion element D1 are added to convert the charges into the voltage of a pixel signal. Since the selection transistor T2 is kept on, the signal voltage of the FD capacitor C1 upon addition is output to the vertical signal line 101. This signal serves as a pixel signal. If necessary, the selection transistor T2 is turned off via the vertical address line 241.

Referring back to FIG. 2, load transistors Ts1 connected to vertical signal lines 101 to 103 form source follower circuits together with the driving transistors Td1 of the pixels 11 on the connected columns. Further, the gate of the load transistor Ts1 is grounded and functions as a current source. A vertical control circuit 200 can select, in a predetermined order, vertical control lines 201 to 203 connected to readout pixels in accordance with the instruction of a control signal from the synchronous control unit 10 via a control input terminal 16.

A sample-and-hold circuit 13 is controlled via SH control lines 49 and 50 and can send, to an output circuit 14, signals sent from pixels via the vertical signal lines 101 to 103. The output circuit 14 includes a current amplifier circuit and voltage amplifier circuit functioning as a differential amplifier circuit. The output circuit 14 amplifies a received signal to an appropriate current or voltage, and outputs the amplified signal to the pre-processing unit 4 via an output terminal 15. An SH control circuit 40 controls the sample-and-hold circuit 13 in accordance with the instruction of a control signal from the synchronous control unit 10 via the control input terminal 16. A horizontal control circuit 400 can select horizontal control lines 401 to 403 in a predetermined order in accordance with the instruction of a control signal from the synchronous control unit 10 via the control input terminal 16.

FIG. 4 exemplifies the arrangement of the sample-and-hold circuit 13. Transistors T49 and T50 function as switches to close or open the circuit when turned on/off via the SH control lines 49 and 50 having the same numbers as those of the transistors T49 and T50. Transistors T421 to T423 function as switches to close or open the circuit when turned on/off via the horizontal control lines 401 to 403. Transistors T441 to T443 function as switches to close or open the circuit when turned on/off via the horizontal control lines 401 to 403. Accumulation capacitors C421 to C423 and C441 to C443 accumulate signals sent via the transistors T49 and T50.

The operation of the sample-and-hold circuit 13 will be explained with reference to FIG. 4. In noise readout in the sample-and-hold circuit 13, the transistor T49 is turned on under the control of the SH control line 49. Noise signals sent to the vertical signal lines 101 to 103 are accumulated in the accumulation capacitors C421 to C423. Then, the transistor T49 is turned off. In pixel signal readout in the sample-and-hold circuit 13, the transistor T50 is turned on under the control of the SH control line 50. Pixel signals sent to the vertical signal lines 101 to 103 are accumulated in the accumulation capacitors C441 to C443. Then, the transistor T50 is turned off.

The horizontal control circuit 400 sequentially selects the horizontal control lines 401 to 403 to control the transistors T421 to T423 and T441 to T443 in accordance with a control signal from the synchronous control unit 10. Noise signals accumulated in the accumulation capacitors C421 to C423 and pixel signals accumulated in the accumulation capacitors C441 to C443 corresponding to the selected horizontal control lines are output to a horizontal noise line 501 and horizontal signal line 502, respectively. As a result, a differential output corresponding to one horizontal row between pixel signals and noise signals is output via the output circuit 14.

A still image shooting mode in which signals are read out from all pixels will be explained. This mode corresponds to (4) of <Control of Still Image Shooting>.

After exposure, the vertical control circuit 200 sequentially selects the vertical control lines 201 to 203 in the image sensor 2. In this operation, signals are first read out from pixels on the first row of the image sensor 2. Prior to pixel signal readout, noise readout is done for one horizontal row. In the sample-and-hold circuit 13, the transistor T49 is turned on via the SH control line 49 to accumulate noise signals sent from the vertical signal lines 101 to 103 in the accumulation capacitors C421 to C423, and then turned off. This operation is noise readout.

Then, pixel signal readout is executed for the same row as that having undergone noise readout. In the sample-and-hold circuit 13, the transistor T50 is turned on via the SH control line 50 to accumulate pixel signals sent from the vertical signal lines 101 to 103 in the accumulation capacitors C441 to C443, and then turned off. This operation is pixel signal readout.

In this description, noise readout and pixel signal readout are executed separately. However, a series of operations from noise readout to pixel signal readout may be performed as continuous signal readout, as described with reference to FIG. 3.

Thereafter, the horizontal control circuit 400 selects the horizontal control lines 401 to 403 in turn. The noise signals are sent to the output circuit 14 via the horizontal noise line 501, whereas the pixel signals are sent to it via the horizontal signal line 502. A differential output between the pixel signals and the noise signals serves as an output from the image sensor 2. This operation is repeated for one horizontal row to read out signals from pixels on the first row. After this operation is done for all the pixels, the still image shooting mode ends.

In the embodiment of the present invention, a noise signal upon resetting the FD capacitor C1 serving as the input of the driving transistor Td1 of a pixel amplifier serving as the amplification means of a pixel is subtracted from a pixel signal. This operation can effectively remove noise generated in the pixel amplifier.

However, even outputs from the sample-and-hold circuits differ from each other owing to variations in transistors and accumulation capacitors which form the sample-and-hold circuit units on respective columns, and a difference in signal path between the noise readout operation and the pixel signal readout operation. This output difference affects a vertical column and appears as vertical streak noise. The vertical streak noise can be reduced by a correction operation described with reference to FIG. 4 of Japanese Patent Laid-Open No. 2000-261730 or FIGS. 4 and 5 of Japanese Patent Laid-Open No. 2006-025146, as described with reference to the image capturing apparatus of FIG. 1. However, the correction precision decreases if the driving transistor of a pixel amplifier in the OB region generates large noise.

A method of reducing noise generated by the driving transistor of a pixel amplifier in the OB region will be explained.

### First Embodiment

The first embodiment of the present invention will be explained with reference to FIGS. 5 to 9 in addition to FIGS. 1 to 4.

FIG. 5 is a view showing the pixel array of an image sensor 2 in the first embodiment of the present invention.

In an effective pixel region 60, photosensitive pixels (FIG. 3) having photo-electric conversion elements are arrayed. In a first OB region 61, light-shielded pixels (first reference pixels for black level) are arrayed. In a second OB region 62, light-shielded pixels (second reference pixels for black level) are arrayed. In FIG. 2, the pixel count of the image sensor 2 is three in both the horizontal and vertical directions for descriptive convenience of the operation. In FIG. 5, the image sensor 2 is assumed to include pixels many enough to perform an OB clamp operation and vertical streak noise correction operation.

FIG. 6 is a view of the layout of a photosensitive pixel (FIG. 3) having a photo-electric conversion element. FIG. 6 does not show elements other than a photo-electric conversion element D1, an FD capacitor C1, the gate, source, and drain of each transistor, and wiring lines. The wiring lines are simplified. The same reference numerals as those in FIG. 3 denote the same building elements.

A photosensitive pixel 110 includes a photo-electric conversion element. A transfer transistor T3 has a gate T3g, a reset transistor T1 has a gate T1g, a driving transistor Td1 has a gate Td1g, and a selection transistor T2 has a gate T2g. A wiring line 308 connects the FD capacitor C1 and the gate Td1g of the driving transistor. The driving transistor Td1 has a gate width W1 and gate length L1. The gate Td1g of the driving transistor may have the channel width W1 and channel length L1. The photosensitive pixels 110 are arrayed in the effective pixel region 60.

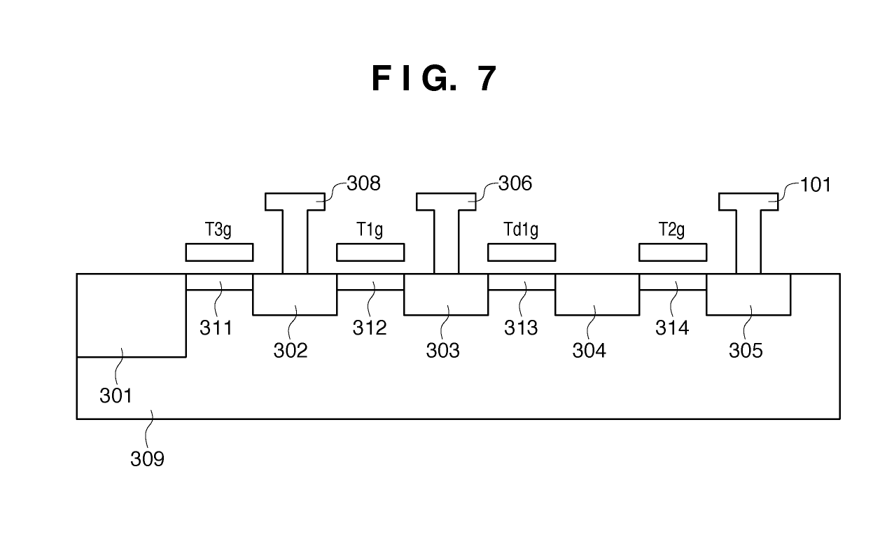

FIG. 7 shows a section containing the channel region of each transistor from the photo-electric conversion element D1 to the connecting portion of the vertical signal line 101 in FIG. 6.

A region 301 functions as a photo-electric conversion element D1. A regions 302 functions as the FD capacitor C1 and also serves as the connecting portion between the drain of the transfer transistor T3 and the source of the reset transistor T1. The region 302 also serves as the connecting portion of the wiring line 308 that connects the FD capacitor C1 and the gate Td1g of the driving transistor.

A region 303 functions as the connecting portion between a power supply Vd and the wiring line 308 and also serves as the connecting portion between the drains of the reset transistor T1 and driving transistor Td1. A region 304 functions as the connecting portion between the source of the driving transistor Td1 and the drain of the selection transistor T2. A region 305 functions as the connecting portion of the vertical signal line 101 and serves as the source of the selection transistor T2. The transfer transistor T3 has a channel 311, the reset transistor T1 has a channel 312, the driving transistor Td1 has a channel 313, and the selection transistor T2 has a channel 314.

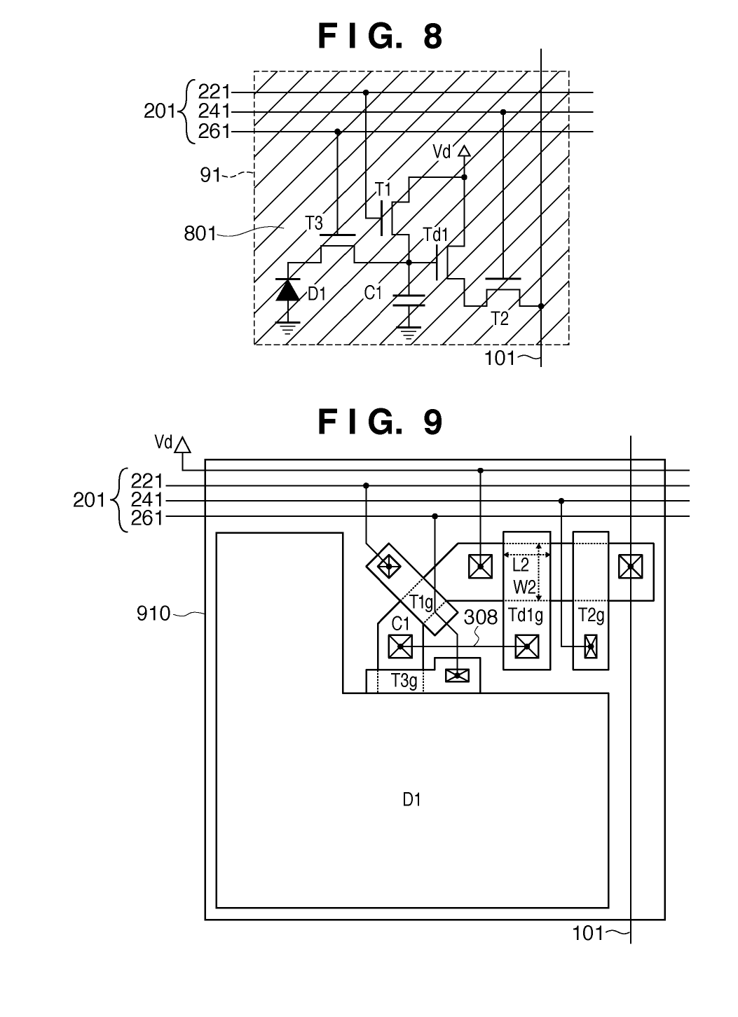

FIG. 8 is a circuit diagram showing a light-shielded pixel having a photo-electric conversion element. A portion surrounded by a dotted line is a light-shielded pixel 91. The light-shielded pixel 91 has the same structure as that of the pixel in FIG. 3 except that it has a light-shielding means 801. FIG. 9 is a view of the layout of the first light-shielded pixel having a photo-electric conversion element. The same reference numerals and symbols as those in FIG. 8 denote the same parts in FIG. 9. Although the light-shielded pixel 91 is shielded from light, the light-shielding means 801 is not illustrated. The light-shielded pixel 91 has the same section as that in FIG. 7.

A first light-shielded pixel 910 has a photo-electric conversion element. The first light-shielded pixel 910 is equal in horizontal and vertical dimensions to the photosensitive pixel 110. The driving transistor Td1 has a gate width (channel width) W2 and a gate length (channel length) L2.

The operation of the image capturing apparatus when the first OB region 61 serves as the HOB region, the second OB region 62 serves as the VOB region, and the first light-shielded pixels 910 are arrayed in the respective regions will be explained.

In the image capturing apparatus of the first embodiment, a pre-processing unit 4 clamps a signal output from the image sensor 2. At this time, a VOB clamp operation can be executed using reference signals for black level read out from the second OB region 62 serving as the VOB region. An HOB clamp operation can be done using reference signals for black level read out from the first OB region 61 serving as the HOB region. VOB clamping may be omitted.

A signal processing unit 5 can perform a vertical streak noise correction operation. More specifically, the signal processing unit 5 generates a correction signal for one line using reference signals for black level read out from the second OB region 62 serving as the VOB region, and subtracts the correction signal from an output signal read out from the effective pixel region 60. Further, the signal processing unit 5 can execute a digital clamp operation. More specifically, the signal processing unit 5 averages reference signals for black level read out from the first OB region 61 serving as the HOB region, and subtracts the average signal from an output signal read out from the effective pixel region 60.

However, if the number of light-shielded pixels in the horizontal direction in the HOB region is insufficient, a clamp error generates horizontal streak noise in the HOB clamp operation by the pre-processing unit 4 under the influence of noise contained in reference signals for black level read out from the first OB region 61. Even in the digital clamp operation by the signal processing unit 5, no accurate reference signal for black level can be generated, and a clamp error causes a problem such as false rising or falling of a signal. Also, if the number of light-shielded pixels in the vertical direction in the VOB region is insufficient, no correction signal can be generated accurately under the influence of noise contained in reference signals for black level in the vertical streak noise correction operation using reference signals for black level read out from the second OB region 62. Consequently, vertical streak noise remains unremoved.

A method of reducing noise generated by the driving transistor of a pixel amplifier in the OB region will be explained for the following three cases.

(1) Case in Which Number of Light-shielded Pixels in Horizontal Direction in HOB Region Is Insufficient

The gate width (channel width) W2 and gate length (channel length) L2 of the driving transistor Td1 in the first OB region 61 serving as the HOB region and the gate width (channel width) W1 and gate length (channel length) L1 of the driving transistor Td1 in the effective pixel region 60 are set to have relations:

W2 of the first OB region>W1 of the effective pixel region, and

L2 of the first OB region>L1 of the effective pixel region

These settings can reduce noise generated by the driving transistor Td1 in the HOB region, preventing a clamp error.

At this time, a noise reduction effect is attained even when

W2 of the first OB region>W1 of the effective pixel region, and

L2 of the first OB region=L1 of the effective pixel region

or when

W2 of the first OB region=W1 of the effective pixel region, and

L2 of the first OB region>L1 of the effective pixel region

The gate width (channel width) W2 and gate length (channel length) L2 of the driving transistor Td1 in the second OB region 62 serving as the VOB region suffice to have relations:

W2 of the second OB region=W1 of the effective pixel region, and

L2 of the second OB region=L1 of the effective pixel region

(2) Case in Which Number of Light-Shielded Pixels in Vertical Direction in VOB Region Is Insufficient

The gate width (channel width) W2 and gate length (channel length) L2 of the driving transistor Td1 in the second OB region 62 serving as the VOB region and the gate width (channel width) W1 and gate length (channel length) L1 of the driving transistor Td1 in the effective pixel region 60 are set to have relations:

W2 of the second OB region>W1 of the effective pixel region, and

L2 of the second OB region>L1 of the effective pixel region

These settings can reduce noise generated by the driving transistor Td1 in the VOB region, preventing a vertical streak noise correction error.

At this time, a noise reduction effect is attained even when

W2 of the second OB region>W1 of the effective pixel region, and

L2 of the second OB region=L1 of the effective pixel region

or when

W2 of the second OB region=W1 of the effective pixel region, and

L2 of the second OB region>L1 of the effective pixel region

The gate width (channel width) W2 and gate length (channel length) L2 of the driving transistor Td1 in the first OB region 61 serving as the HOB region suffice to have relations:

W2 of the first OB region=W1 of the effective pixel region, and

L2 of the first OB region=L1 of the effective pixel region

(3) Case in Which Number of Light-Shielded Pixels in Horizontal Direction in HOB Region and Number of Light-Shielded Pixels in Vertical Direction in VOB Region Are Insufficient

The gate width (channel width) W2 and gate length (channel length) L2 of the driving transistor Td1 in the first OB region 61 serving as the HOB region, the gate width (channel width) W2 and gate length (channel length) L2 of the driving transistor Td1 in the second OB region 62 serving as the VOB region, and the gate width (channel width) W1 and gate length (channel length) L1 of the driving transistor Td1 in the effective pixel region 60 are set to have relations:

W2 of the first OB region>W1 of the effective pixel region,

L2 of the first OB region>L1 of the effective pixel region,

W2 of the second OB region>W1 of the effective pixel region, and

L2 of the second OB region>L1 of the effective pixel region

These settings can prevent a clamp error by reducing noise generated by the driving transistor Td1 in the HOB region. In addition, these settings can prevent a vertical streak noise correction error by reducing noise generated by the driving transistor Td1 in the VOB region.

At this time, a noise reduction effect is achieved even by setting either W2 or L2 of the first OB region or either W2 or L2 of the second OB region to be equal to a corresponding one of W1 and L1 of the effective pixel region.

HOB clamping and vertical streak noise correction will be compared. HOB clamping is done using not only signals from light-shielded pixels on a current row but also signals from light-shielded pixels on a preceding row. In contrast, in vertical streak noise correction, signals from vertical pixels in the VOB region are averaged to generate a correction signal for the current column. In principle, the number of light-shielded pixels available in vertical streak noise correction is, therefore, smaller than that in HOB clamping. Vertical streak noise correction is more readily affected by noise generated by the driving transistor Td1.

In general, the effective pixel region of an image sensor is long in the horizontal direction. The influence of an increase in the VOB region on an increase in image sensor area is larger than that of an increase in the HOB region. Hence, the number of light-shielded pixels in the vertical direction often becomes short.

Considering this,

W2 of the second OB region>W2 of the first OB region>W1 of the effective pixel region, and

L2 of the second OB region>L2 of the first OB region>L1 of the effective pixel region

These settings can further reduce noise generated by the driving transistor Td1 in the VOB region, preventing a vertical streak noise correction error sensitive to noise.

At this time, a noise reduction effect can be obtained even by setting either W2 or L2 of the first OB region or either W2 or L2 of the second OB region to be equal to a corresponding one of W1 and L1 of the effective pixel region.

### Second Embodiment

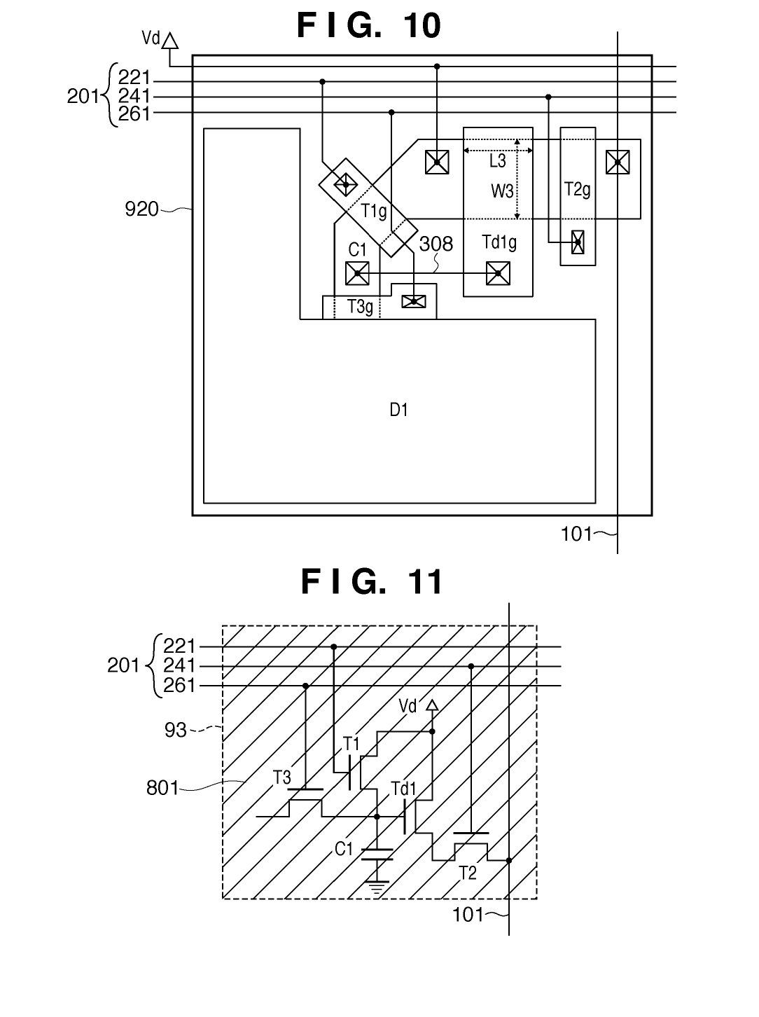

An image capturing apparatus according to the second embodiment of the present invention will be explained with reference to FIG. 10 in addition to FIGS. 1 to 9. In the second embodiment, the basic arrangement and operation of the image capturing apparatus and those of an image sensor are the same as those in the first embodiment. The second embodiment will be explained by applying the same drawings and reference numerals as those in the first embodiment.

FIG. 10 is a view of the layout of the second light-shielded pixel having a photo-electric conversion element. The same reference numerals and symbols as those in FIG. 8 denote the same parts. Although the pixel is shielded from light, a light-shielding means 801 is not illustrated. The light-shielded pixel has the same section as that in FIG. 7.

A second light-shielded pixel 920 has a photo-electric conversion element. The second light-shielded pixel 920 is equal in horizontal and vertical lengths to a photosensitive pixel 110. A driving transistor Td1 has a gate width (channel width) W3 and a gate length (channel length) L3.

In the second light-shielded pixel 920, the area of a photo-electric conversion element D1 is reduced to increase the gate width (channel width) W3 and gate length (channel length) L3. The vertical dimension of the photo-electric conversion element D1 is reduced to increase the gate width (channel width) W3. The horizontal dimension of the photo-electric conversion element D1 is reduced to increase the gate length (channel length) L3. Since the second light-shielded pixel 920 need not be sensitive to light, reducing the area of the photo-electric conversion element D1 hardly affects a readout reference signal for black level.

A large gate width (channel width) W3 and gate length (channel length) L3 can reduce noise generated by the driving transistor Td1 of the second light-shielded pixel 920, in comparison with the photosensitive pixel 110.

At this time, it is also possible to increase only the gate width (channel width) W3 while setting the gate length (channel length) L3 to be equal to L1 of the photosensitive pixel 110 not to reduce the horizontal dimension of the photo-electric conversion element D1. Even in this case, a noise reduction effect is attained. It is also possible to increase only the gate length (channel length) L3 while setting the gate width (channel width) W3 to be equal to W1 of the photosensitive pixel 110 not to reduce the vertical dimension of the photo-electric conversion element D1. Even in this case, a noise reduction effect is achieved.

The operation of the image capturing apparatus in the second embodiment when a first OB region 61 in FIG. 5 serves as the HOB region and a second OB region 62 serves as the VOB region will be explained.

(1) Case in which Second Light-Shielded Pixels 920 are Arrayed in Both First and Second OB Regions 61 and 62

It is apparent that a noise reduction effect is obtained by setting the gate widths (channel widths) W3 and gate lengths (channel lengths) L3 of the first and second OB regions 61 and 62 to have the same relations as those in the first embodiment with the gate width (channel width) W1 and gate length (channel length) L1 of an effective pixel region 60.

(2) Case in Which First Light-Shielded Pixels 910 are Arrayed in First OB Region 61 and Second Light-Shielded Pixels 920 are Arrayed in Second OB Region 62

It is apparent that a noise reduction effect is attained by setting the gate width (channel width) W2 and gate length (channel length) L2 of the first OB region 61 to have the same relations as those in the first embodiment with the gate width (channel width) W1 and gate length (channel length) L1 of the effective pixel region 60.

Also, a noise reduction effect is evidently attained by setting the gate width (channel width) W3 and gate length (channel length) L3 of the second OB region 62 to have the same relations as those in the first embodiment with the gate width (channel width) W1 and gate length (channel length) L1 of the effective pixel region 60.

In addition,

W3 of the second OB region>W2 of the first OB region>W1 of the effective pixel region, and

L3 of the second OB region>L2 of the first OB region>L1 of the effective pixel region

These settings can further reduce noise generated by the driving transistor Td1 in the VOB region, preventing a vertical streak noise correction error sensitive to noise.

At this time, a noise reduction effect is obtained even by setting either W2 or L2 of the first OB region or either W3 or L3 of the second OB region to be equal to a corresponding one of W1 and L1 of the effective pixel region.

The second embodiment apparently has a noise reduction effect even when the second light-shielded pixels 920 are arrayed in the first OB region 61 and the first light-shielded pixels 910 are arrayed in the second OB region 62, similar to (2) of the second embodiment.

In the second embodiment, the vertical dimension of the photo-electric conversion element D1 is reduced to increase the gate width (channel width) W3. The horizontal dimension of the photo-electric conversion element D1 is reduced to increase the gate length (channel length) L3. However, a combination of the horizontal and vertical directions in which the area of the photo-electric conversion element D1 is reduced, and directions (horizontal and vertical directions) in which the gate width (channel width) W and gate length (channel length) L are increased may be reversed depending on the layout of the driving transistor Td1 in order to increase the gate width (channel width) W and gate length (channel length) L.

### Third Embodiment

An image capturing apparatus according to the third embodiment of the present invention will be explained with reference to FIGS. 11 to 13 in addition to FIGS. 1 to 10. In the third embodiment, the basic arrangement and operation of the image capturing apparatus and those of an image sensor are the same as those in the first and second embodiments. The third embodiment will be explained by applying the same drawings and reference numerals as those in the first and second embodiments.

FIG. 11 is a view showing a light-shielded pixel having no photo-electric conversion element. A portion surrounded by a dotted line is a light-shielded pixel 93. The light-shielded pixel 93 has the same structure as that of the pixel in FIG. 3 except that it has a light-shielding means 801 and does not include a photo-electric conversion element D1.

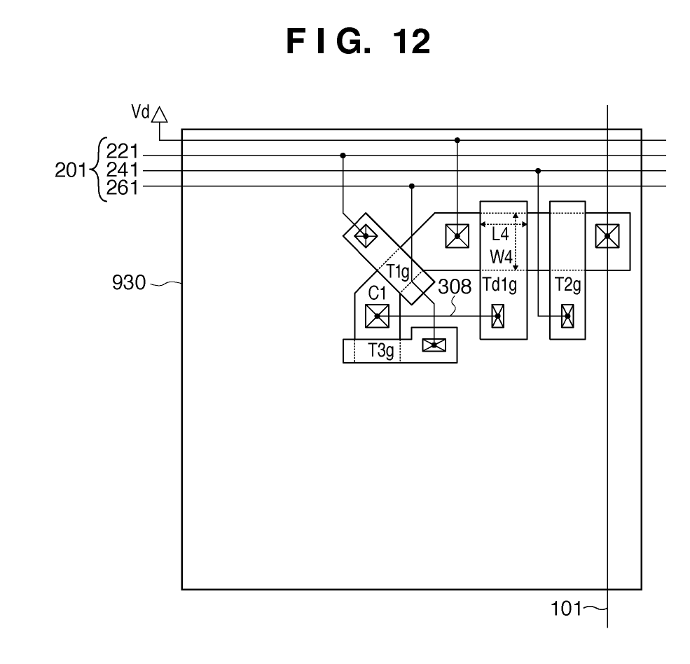

FIG. 12 is a view of the layout of the third light-shielded pixel having no photo-electric conversion element. This layout is obtained by removing the photo-electric conversion element D1 from the layout in FIG. 9. The same reference numerals and symbols as those in FIG. 11 denote the same parts in FIG. 12. Although the pixel is shielded from light, the light-shielding means 801 is not illustrated. The third light-shielded pixel has the same section as that in FIG. 7 except that it does not include the photo-electric conversion element D1 represented by a region 301 in FIG. 7.

A third light-shielded pixel 930 does not include a photo-electric conversion element. The third light-shielded pixel 930 is equal in horizontal and vertical dimensions to a photosensitive pixel 110. A driving transistor Td1 has a gate width (channel width) W4 and a gate length (channel length) L4.

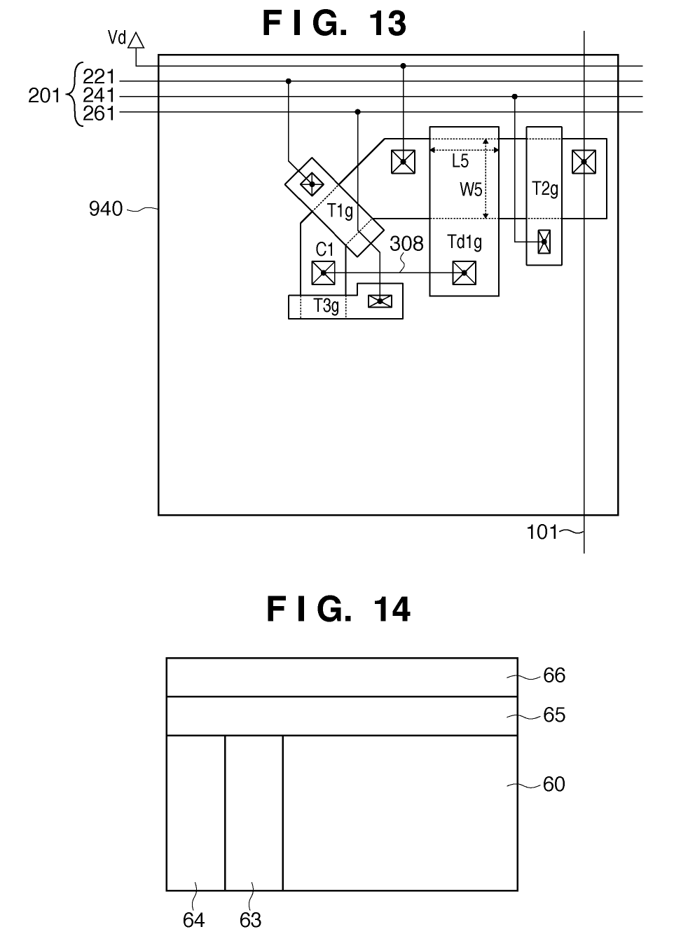

FIG. 13 is a view of the layout of the fourth light-shielded pixel having no photo-electric conversion element. This layout is obtained by removing the photo-electric conversion element D1 from the layout in FIG. 10. The same reference numerals and symbols as those in FIG. 11 denote the same parts in FIG. 13. Although the pixel is shielded from light, the light-shielding means 801 is not illustrated. The fourth light-shielded pixel has the same section as that in FIG. 7 except that it does not include the photo-electric conversion element D1 represented by the region 301 in FIG. 7.

A fourth light-shielded pixel 940 does not include a photo-electric conversion element. The fourth light-shielded pixel 940 is equal in horizontal and vertical dimensions to the photosensitive pixel 110. The driving transistor Td1 has a gate width (channel width) W5 and a gate length (channel length) L5.

The fourth light-shielded pixel 940 adopts a layout which increases the gate width (channel width) W5 and gate length (channel length) L5 by the same method as that of reducing the area of the photo-electric conversion element D1 in FIG. 10.

A large gate width (channel width) W and gate length (channel length) L of the third and fourth light-shielded pixels 930 and 940 can reduce noise generated by the driving transistors Td1 of the third and fourth light-shielded pixels 930 and 940, compared to the photosensitive pixel 110.

At this time, a noise reduction effect is attained even by increasing only the gate width (channel width) W3 while setting the gate length (channel length) L3 to be equal to L1 of the photosensitive pixel 110. Further, a noise reduction effect is obtained even by increasing only the gate length (channel length) L3 while setting the gate width (channel width) W3 to be equal to W1 of the photosensitive pixel 110.

Because of the absence of the photo-electric conversion element D1, the third and fourth light-shielded pixels 930 and 940 are free from the influence of a dark current generated in the photo-electric conversion element D1. Noise in a readout reference signal for black level becomes much smaller than that generated by first and second light-shielded pixels 910 and 920.

The operation of the image capturing apparatus in the third embodiment when a first OB region 61 in FIG. 5 serves as the HOB region and a second OB region 62 serves as the VOB region will be explained.

(1) Case in Which First Light-Shielded Pixels 910 are Arrayed in First OB Region 61 and Third Light-Shielded Pixels 930 are Arrayed in Second OB Region 62

It is apparent that a noise reduction effect is obtained by setting the gate width (channel width) W2 and gate length (channel length) L2 of the first OB region 61 to have the same relations as those in the first embodiment with the gate width (channel width) W1 and gate length (channel length) L1 of an effective pixel region 60.

Similarly, a noise reduction effect is obviously obtained by setting the gate width (channel width) W4 and gate length (channel length) L4 of the second OB region 62 to have the same relations as those in the first embodiment with the gate width (channel width) W1 and gate length (channel length) L1 of the effective pixel region 60.

The third light-shielded pixels 930 arrayed in the VOB region do not have the photo-electric conversion element D1. Noise in a readout reference signal for black level therefore becomes much smaller than that generated by the first light-shielded pixel 910. The third light-shielded pixel 930 is effective for vertical streak noise correction sensitive to noise.

In addition,

W4 of the second OB region>W2 of the first OB region>W1 of the effective pixel region, and

L4 of the second OB region>L2 of the first OB region>L1 of the effective pixel region

These settings can further reduce noise generated by the driving transistor Td1 in the VOB region, further preventing a vertical streak noise correction error sensitive to noise.

At this time, a noise reduction effect is obtained even by setting either W2 or L2 of the first OB region or either W4 or L4 of the second OB region to be equal to a corresponding one of W1 and L1 of the effective pixel region.

The third embodiment apparently has a noise reduction effect in both a case in which the second light-shielded pixels 920 are arrayed in the first OB region 61 and a case in which the fourth light-shielded pixels 940 are arrayed in the second OB region 62, similar to (1) in the third embodiment.

In the third embodiment, a combination of directions (horizontal and vertical directions) in which the gate width (channel width) W and gate length (channel length) L are increased may be reversed depending on the layout of the driving transistor Td1 in order to increase the gate width (channel width) W and gate length (channel length) L.

### Fourth Embodiment

An image capturing apparatus according to the fourth embodiment of the present invention will be explained with reference to FIGS. 14 to 18 in addition to FIGS. 1 to 13. In the fourth embodiment, the basic arrangement and operation of the image capturing apparatus and those of an image sensor are the same as those in the first to third embodiments. The fourth embodiment will be explained by applying the same drawings and reference numerals as those in the first to third embodiments.

FIG. 14 is a view exemplifying the pixel array of an image sensor 2 in the fourth embodiment. Photosensitive pixels 110 having photo-electric conversion elements are arrayed in an effective pixel region 60. Light-shielded pixels are arrayed in a third OB region 63, fourth OB region 64, fifth OB region 65, and sixth OB region 66.

The operation of the image capturing apparatus when the third OB region 63 serves as the first HOB region, the fourth OB region 64 serves as the second HOB region, the fifth OB region 65 serves as the first VOB region, and the sixth OB region 66 serves as the second VOB region will be explained.

In the image capturing apparatus of the fourth embodiment, a pre-processing unit 4 clamps a signal output from the image sensor 2. At this time, a VOB clamp operation is executed using reference signals for black level read out from the sixth OB region 66 serving as the second VOB region. An HOB clamp operation is performed using reference signals for black level read out from the fourth OB region 64 serving as the second HOB region. VOB clamping may be omitted.

At this time, it is also possible to perform the VOB clamp operation including the fifth OB region 65 serving as the first VOB region or the HOB clamp operation including the third OB region 63 serving as the first HOB region.

A signal processing unit 5 executes a vertical streak noise correction operation. More specifically, the signal processing unit 5 generates a correction signal for one line using reference signals for black level read out from the fifth OB region 65 serving as the first VOB region, and subtracts the correction signal from an output signal read out from the effective pixel region 60.

Further, the signal processing unit 5 executes a digital clamp operation. More specifically, the signal processing unit 5 averages reference signals for black level read out from the third OB region 63 serving as the first HOB region, and subtracts the average signal from an output signal read out from the effective pixel region 60.

The first to third embodiments have revealed that any of first, second, third, and fourth light-shielded pixels 910, 920, 930, and 940 arrayed in the third, fourth, fifth, and sixth OB regions 63, 64, 65, and 66 can reduce noise generated by the driving transistor Td1 more effectively than the photosensitive pixel 110.

However, it is desired to arrange light-shielded pixels more properly because light-shielded pixels having photo-electric conversion elements and those having no photo-electric conversion element surround the effective pixel region 60 where photosensitive pixels having photo-electric conversion elements are arrayed.

Digital clamping executed by the signal processing unit 5 can, for example, use the average of signals from reference pixels for black level in the entire third OB region 63. In contrast, the pre-processing unit 4 performs HOB clamping using the fourth OB region 64 including reference pixels for black level read out before a line to be clamped. For this reason, the number of light-shielded pixels used for HOB clamping is smaller than that used for digital clamping, so HOB clamping is more readily affected by noise generated by the driving transistor Td1.

From this, the gate width (channel width) W and gate length (channel length) L of the fourth OB region 64 are preferably set larger than those of the third OB region 63.

VOB clamping executed by the pre-processing unit 4 suffices to end before reading out signals from the effective pixel region 60. The VOB clamp operation can be done using signals from reference pixels for black level from the entire sixth OB region 66. However, in vertical streak noise correction executed by the signal processing unit 5 using the fifth OB region 65, signals from vertical pixels in the fifth OB region 65 are averaged to generate a correction signal for the column.

The number of light-shielded pixels used for vertical streak noise correction is thus smaller than that used for VOB clamping, and vertical streak noise correction is more readily affected by noise generated by the driving transistor Td1.

Hence, the gate width (channel width) W and gate length (channel length) L of the fifth OB region 65 are preferably set larger than those of the sixth OB region 66.

Conditions for light-shielded pixels arrayed in the OB region will be explained.

(1) Case in which First Light-Shielded Pixels 910, Second Light-Shielded Pixels 920, Third Light-Shielded Pixels 930, or Fourth Light-Shielded Pixels 940 are Arrayed in Both Third and Fourth OB Regions 63 and 64 Serving as HOB Regions

At this time, the conditions of the gate widths (channel widths) W and gate lengths (channel lengths) L of the third and fourth OB regions are set to

W of the fourth OB region>W of the third OB region>W1 of the effective pixel region, and

L of the fourth OB region>L of the third OB region>L1 of the effective pixel region

Under these conditions, noise generated by the driving transistor Td1 in the fourth OB region 64 can be further reduced, further preventing an HOB clamping correction error sensitive to noise.

(2) Case in which Two Types Out of First Light-Shielded Pixels 910, Second Light-Shielded Pixels 920, Third Light-Shielded Pixels 930, and Fourth Light-Shielded Pixels 940 are Combined and Arrayed in Third and Fourth OB Regions 63 and 64 Serving as Hob Regions

When the first light-shielded pixels 910 are arrayed in the third OB region 63, the second light-shielded pixels 920, third light-shielded pixels 930, or fourth light-shielded pixels 940 are arrayed in the fourth OB region 64. These light-shielded pixels have a margin to increase the gate width (channel width) W and gate length (channel length) L, compared to the first light-shielded pixels 910, satisfying condition (1) in the fourth embodiment.

Similarly, when the second light-shielded pixels 920 are arrayed in the third OB region 63, the third light-shielded pixels 930 or fourth light-shielded pixels 940 are arrayed in the fourth OB region 64. When the third light-shielded pixels 930 are arrayed in the third OB region 63, the fourth light-shielded pixels 940 are arrayed in the fourth OB region 64. In these cases, condition (1) in the fourth embodiment can be satisfied.

Accordingly, noise generated by the driving transistor Td1 in the fourth OB region 64 can be further reduced, further preventing an HOB clamping correction error sensitive to noise.

(3) Case in which First Light-Shielded Pixels 910, Second Light-Shielded Pixels 920, Third Light-Shielded Pixels 930, or Fourth Light-Shielded Pixels 940 are Arrayed in Both Fifth and Sixth OB Regions 65 and 66 Serving as VOB Regions

At this time, the conditions of the gate widths (channel widths) W and gate lengths (channel lengths) L of the fifth and sixth OB regions are set to

W of the fifth OB region>W of the sixth OB region>W1 of the effective pixel region, and

L of the fifth OB region>L of the sixth OB region>L1 of the effective pixel region

Under these conditions, noise generated by the driving transistor Td1 in the fifth OB region 65 can be further reduced, further preventing a vertical streak noise correction error sensitive to noise.

(4) Case in which Two Types Out of First Light-Shielded Pixels 910, Second Light-Shielded Pixels 920, Third Light-Shielded Pixels 930, and Fourth Light-Shielded Pixels 940 are Combined and Arrayed in Fifth and Sixth OB Regions 65 and 66 Serving as VOB Regions

When the first light-shielded pixels 910 are arrayed in the sixth OB region 66, the second light-shielded pixels 920, third light-shielded pixels 930, or fourth light-shielded pixels 940 are arrayed in the fifth OB region 65. These light-shielded pixels have a margin to increase the gate width (channel width) W and gate length (channel length) L, compared to the first light-shielded pixels 910, satisfying condition (1) in the fourth embodiment.

Similarly, when the second light-shielded pixels 920 are arrayed in the sixth OB region 66, the third light-shielded pixels 930 or fourth light-shielded pixels 940 are arrayed in the fifth OB region 65. When the third light-shielded pixels 930 are arrayed in the sixth OB region 66, the fourth light-shielded pixels 940 are arrayed in the fifth OB region 65. In these cases, condition (1) in the fourth embodiment can be satisfied.

Noise generated by the driving transistor Td1 in the fifth OB region 65 can be further reduced, further preventing a vertical streak noise correction error sensitive to noise.

Conditions (1) and (2) for the HOB region and conditions (3) and (4) for the VOB region may be combined.

Modifications to the fourth embodiment will be explained.

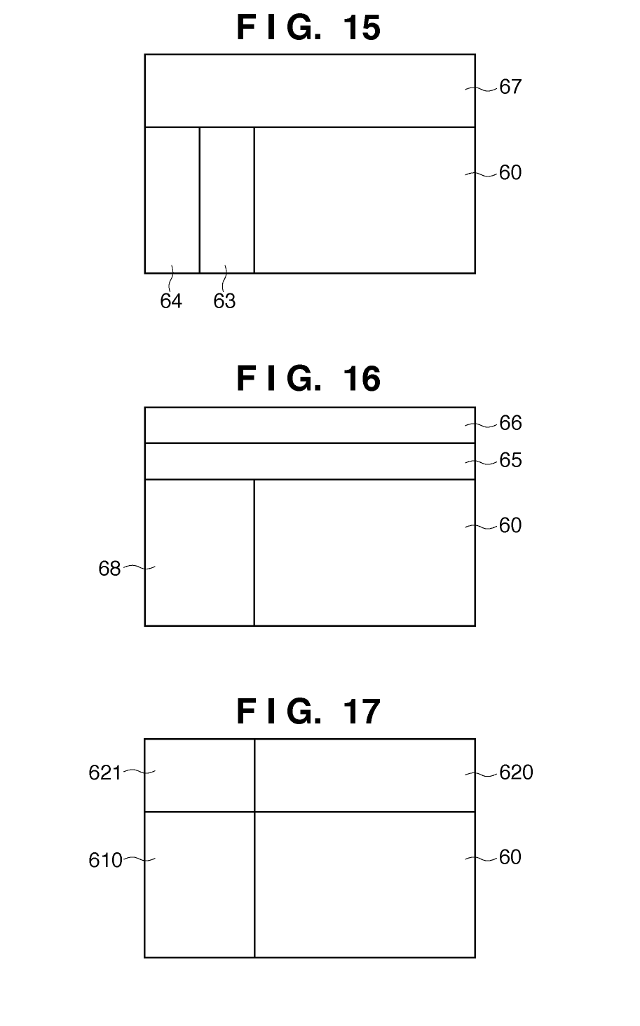

FIG. 15 is a view showing a modification of the pixel array of the image sensor 2 in the fourth embodiment. The photosensitive pixels 110 having photo-electric conversion elements are arrayed in the effective pixel region 60. Light-shielded pixels are arrayed in the third and fourth OB regions 63 and 64 and a seventh OB region 67.

As is apparent from the first to third embodiments, the first, second, third, and fourth light-shielded pixels 910, 920, 930, and 940 reduce noise generated by the driving transistor Td1 more effectively than the photosensitive pixel 110 regardless of which of them are arrayed in the third, fourth, and seventh OB regions 63, 64, and 67.

The third OB region 63 serves as the first HOB region, the fourth OB region 64 serves as the second HOB region, and the seventh OB region 67 serves as the third VOB region.

In the third and fourth OB regions 63 and 64, light-shielded pixels are arrayed to meet conditions (1) and (2) for the HOB region in the fourth embodiment. The seventh OB region 67 operates similarly to the VOB region in the first embodiment. Noise generated by the driving transistor Td1 in the fourth OB region 64 can therefore be further reduced, further preventing an HOB clamping correction error sensitive to noise.

FIG. 16 is a view showing another modification of the pixel array of the image sensor 2 in the fourth embodiment. The photosensitive pixels 110 having photo-electric conversion elements are arrayed in the effective pixel region 60. Light-shielded pixels are arrayed in the fifth and sixth OB regions 65 and 66 and an eighth OB region 68.

The first to third embodiments have clarified that the first, second, third, and fourth light-shielded pixels 910, 920, 930, and 940 reduce noise generated by the driving transistor Td1 more effectively than the photosensitive pixel 110 regardless of which of them are arrayed in the fifth, sixth, and eighth OB regions 65, 66, and 68.

The fifth OB region 65 serves as the first VOB region, the sixth OB region 66 serves as the second VOB region, and the eighth OB region 68 serves as the third HOB region.

In the fifth and sixth OB regions 65 and 66, light-shielded pixels are arrayed to meet conditions (3) and (4) for the VOB region in the fourth embodiment. The eighth OB region 68 operates similarly to the HOB region in the first embodiment. Noise generated by the driving transistor Td1 in the fifth OB region 65 can therefore be further reduced, further preventing a vertical streak noise correction error sensitive to noise.

FIG. 17 is a view showing still another modification of the pixel array in FIG. 5. The photosensitive pixels 110 having photo-electric conversion elements are arrayed in the effective pixel region 60. Light-shielded pixels are arrayed in OB regions 610, 620, and 621.

The first to third embodiments have revealed that the first, second, third, and fourth light-shielded pixels 910, 920, 930, and 940 reduce noise generated by the driving transistor Td1 more effectively than the photosensitive pixel 110 regardless of which of them are arrayed in the OB regions 610, 620, and 621.

In FIG. 17, the second OB region 62 serving as the VOB region in the pixel array of FIG. 5 is divided into the OB regions 620 and 621 in accordance with the HOB region width. The OB region 620 operates similarly to the VOB region in the first embodiment. To the contrary, the OB region 621 may be used for either or both of HOB and VOB.

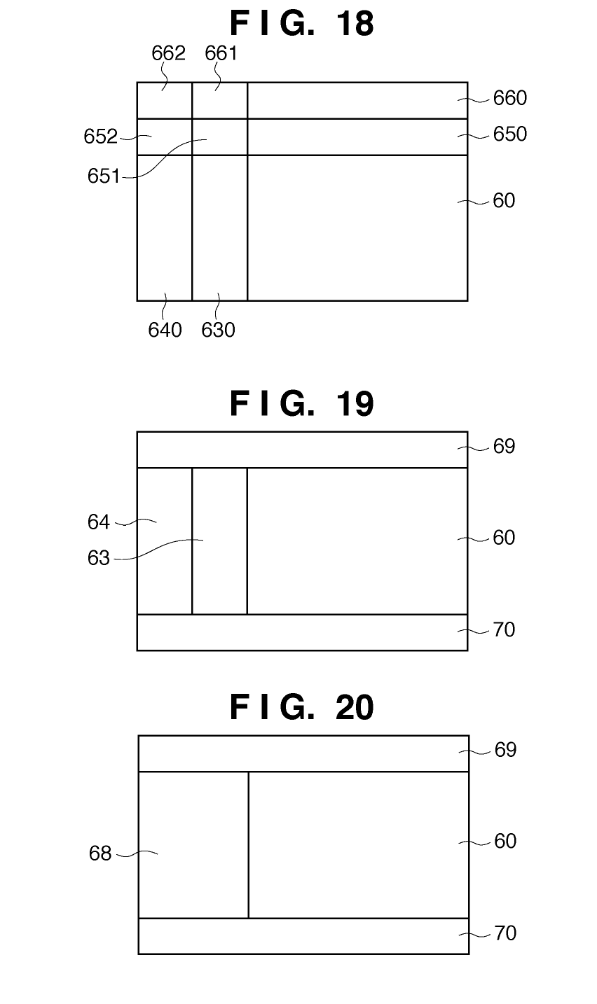

FIG. 18 is a view showing still another modification of the pixel array in FIG. 14. The photosensitive pixels 110 having photo-electric conversion elements are arrayed in the effective pixel region 60. Light-shielded pixels are arrayed in OB regions 630, 640, 650, 651, 652, 660, 661, and 662.

As is apparent from the first to third embodiments, the first, second, third, and fourth light-shielded pixels 910, 920, 930, and 940 reduce noise generated by the driving transistor Td1 more effectively than the photosensitive pixel 110 regardless of which of them are arrayed in the OB regions 630, 640, 650, 651, 652, 660, 661, and 662.

In FIG. 18, the fifth and sixth OB regions 65 and 66 serving as VOB regions in the pixel array of FIG. 14 are divided into the OB regions 650, 651, 652, 660, 661, and 662 in accordance with the HOB region width. The OB regions 630, 640, 650, and 660 operate similarly to the first HOB region, second HOB region, first VOB, and second VOB region, respectively. In contrast, the OB regions 651, 652, 661, and 662 may be used for either or both of HOB and VOB.

### Fifth Embodiment

An image capturing apparatus according to the fifth embodiment of the present invention will be explained with reference to FIGS. 19 to 21 in addition to FIGS. 1 to 18. In the fifth embodiment, the basic arrangement and operation of the image capturing apparatus and those of an image sensor are the same as those in the first to fourth embodiments. The fifth embodiment will be explained by applying the same drawings and reference numerals as those in the first to fourth embodiments.

FIG. 19 is a view exemplifying the pixel array of an image sensor 2 in the fifth embodiment. Photosensitive pixels 110 having photo-electric conversion elements are arrayed in an effective pixel region 60. Light-shielded pixels are arrayed in a third OB region 63, fourth OB region 64, ninth OB region 69, and 10th OB region 70.

The operation of the image capturing apparatus when the third OB region 63 serves as the first HOB region, the fourth OB region 64 serves as the second HOB region, the ninth OB region 69 serves as the fourth VOB region, and the 10th OB region 70 serves as the fifth VOB region will be explained.

In the image capturing apparatus of the fifth embodiment, a pre-processing unit 4 clamps a signal output from the image sensor 2. At this time, a VOB clamp operation is executed using reference signals for black level read out from the ninth OB region 69 serving as the fourth VOB region. An HOB clamp operation is performed using reference signals for black level read out from the fourth OB region 64 serving as the second HOB region. VOB clamping may be omitted. The HOB clamp operation may be done including the third OB region 63 serving as the first HOB region.

A signal processing unit 5 executes a vertical streak noise correction operation. More specifically, the signal processing unit 5 generates a correction signal for one line using reference signals for black level read out from the 10th OB region 70 serving as the fifth VOB region, and subtracts the correction signal from an output signal read out from the effective pixel region 60.

In the pixel array of the image sensor 2 in FIG. 19, the 10th OB region 70 serving as the fifth VOB region is arranged below the effective pixel region 60. Thus, vertical streak noise correction is executed for the next shot image.

Further, the signal processing unit 5 executes a digital clamp operation. More specifically, the signal processing unit 5 averages reference signals for black level read out from the third OB region 63 serving as the first HOB region, and subtracts the average signal from an output signal read out from the effective pixel region 60.

The first to third embodiments have revealed that first, second, third, and fourth light-shielded pixels 910, 920, 930, and 940 reduce noise generated by a driving transistor Td1 more effectively than the photosensitive pixel 110 regardless of which of them are arrayed in the third, fourth, ninth, and 10th OB regions 63, 64, 69, and 70.

However, it is desired to arrange light-shielded pixels more properly because light-shielded pixels having photo-electric conversion elements and those having no photo-electric conversion element surround the effective pixel region 60 where photosensitive pixels having photo-electric conversion elements are arrayed, similar to the fourth embodiment.

An operation using light-shielded pixels in the VOB region and an operation using light-shielded pixels in the HOB region are the same as those in the fourth embodiment. Therefore, only conditions for light-shielded pixels arrayed in the OB regions will be described.

(1) Case in which First Light-Shielded Pixels 910, Second Light-Shielded Pixels 920, Third Light-Shielded Pixels 930, or Fourth Light-Shielded Pixels 940 are Arrayed in Both Third and Fourth OB Regions 63 and 64 Serving as HOB Regions, Similar to

### Fourth Embodiment

At this time, the conditions of the gate widths (channel widths) W and gate lengths (channel lengths) L of the third and fourth OB regions are set to

W of the fourth OB region>W of the third OB region>W1 of the effective pixel region, and

L of the fourth OB region>L of the third OB region>L1 of the effective pixel region

Under these conditions, noise generated by the driving transistor Td1 in the fourth OB region 64 can be further reduced, further preventing an HOB clamping correction error sensitive to noise.

(2) Case in which Two Types Out of First Light-Shielded Pixels 910, Second Light-Shielded Pixels 920, Third Light-Shielded Pixels 930, and Fourth Light-Shielded Pixels 940 are Combined and Arrayed in Third and Fourth OB Regions 63 and 64 Serving as HOB Regions, Similar to Fourth Embodiment

When the first light-shielded pixels 910 are arrayed in the third OB region 63, the second light-shielded pixels 920, third light-shielded pixels 930, or fourth light-shielded pixels 940 are arrayed in the fourth OB region 64. These light-shielded pixels have a margin to increase the gate width (channel width) W and gate length (channel length) L, compared to the first light-shielded pixels 910, satisfying condition (1) in the fifth embodiment.

Similarly, when the second light-shielded pixels 920 are arrayed in the third OB region 63, the third light-shielded pixels 930 or fourth light-shielded pixels 940 are arrayed in the fourth OB region 64. When the third light-shielded pixels 930 are arrayed in the third OB region 63, the fourth light-shielded pixels 940 are arrayed in the fourth OB region 64. In these cases, condition (1) in the fifth embodiment can be satisfied.

Hence, noise generated by the driving transistor Td1 in the fourth OB region 64 can be further reduced, further preventing an HOB clamping correction error sensitive to noise.

(3) Case in which First Light-Shielded Pixels 910, Second Light-Shielded Pixels 920, Third Light-Shielded Pixels 930, or Fourth Light-Shielded Pixels 940 are Arrayed in Both Ninth and 10th OB Regions 69 and 70 Serving as VOB Regions

At this time, the conditions of the gate widths (channel widths) W and gate lengths (channel lengths) L of the ninth and 10th OB regions are set to

W of the 10th OB region>W of the ninth OB region>W1 of the effective pixel region, and

L of the 10th OB region>L of the ninth OB region>L1 of the effective pixel region

Under these conditions, noise generated by the driving transistor Td1 in the 10th OB region 70 can be further reduced, further preventing a vertical streak noise correction error sensitive to noise.

(4) Case in which Two Types Out of First Light-Shielded Pixels 910, Second Light-Shielded Pixels 920, Third Light-Shielded Pixels 930, and Fourth Light-Shielded Pixels 940 are Combined and Arrayed in Ninth and 10th OB Regions 69 and 70 Serving as VOB Regions

When the first light-shielded pixels 910 are arrayed in the ninth OB region 69, the second light-shielded pixels 920, third light-shielded pixels 930, or fourth light-shielded pixels 940 are arrayed in the 10th OB region 70. These light-shielded pixels have a margin to increase the gate width (channel width) W and gate length (channel length) L, compared to the first light-shielded pixels 910, satisfying condition (1) in the fifth embodiment.

Similarly, when the second light-shielded pixels 920 are arrayed in the ninth OB region 69, the third light-shielded pixels 930 or fourth light-shielded pixels 940 are arrayed in the 10th OB region 70. When the third light-shielded pixels 930 are arrayed in the ninth OB region 69, the fourth light-shielded pixels 940 are arrayed in the 10th OB region 70. In these cases, condition (1) in the fifth embodiment can be satisfied.

Noise generated by the driving transistor Td1 in the 10th OB region 70 can be further reduced, further preventing a vertical streak noise correction error sensitive to noise.

Conditions (1) and (2) for the HOB region and conditions (3) and (4) for the VOB region may be combined.

Modifications to the fifth embodiment will be explained.

FIG. 20 is a view showing a modification of the pixel array of the image sensor 2 in the fifth embodiment. The photosensitive pixels 110 having photo-electric conversion elements are arrayed in the effective pixel region 60. Light-shielded pixels are arrayed in an eighth OB region 68 and the ninth and 10th OB regions 69 and 70.

The first to third embodiments have revealed that the first, second, third, and fourth light-shielded pixels 910, 920, 930, and 940 reduce noise generated by the driving transistor Td1 more effectively than the photosensitive pixel 110 regardless of which of them are arrayed in the eighth, ninth, and 10th OB regions 68, 69, and 70.

The eighth OB region 68 serves as the third HOB region, the ninth OB region 69 serves as the fourth VOB region, and the 10th OB region 70 serves as the fifth VOB region.

The eighth OB region 68 operates similarly to the HOB region in the first embodiment. In the ninth and 10th OB regions 69 and 70, light-shielded pixels are arrayed to meet conditions (3) and (4) for the VOB region in the fifth embodiment. Noise generated by the driving transistor Td1 in the 10th OB region 70 can therefore be further reduced, further preventing a vertical streak noise correction error sensitive to noise.

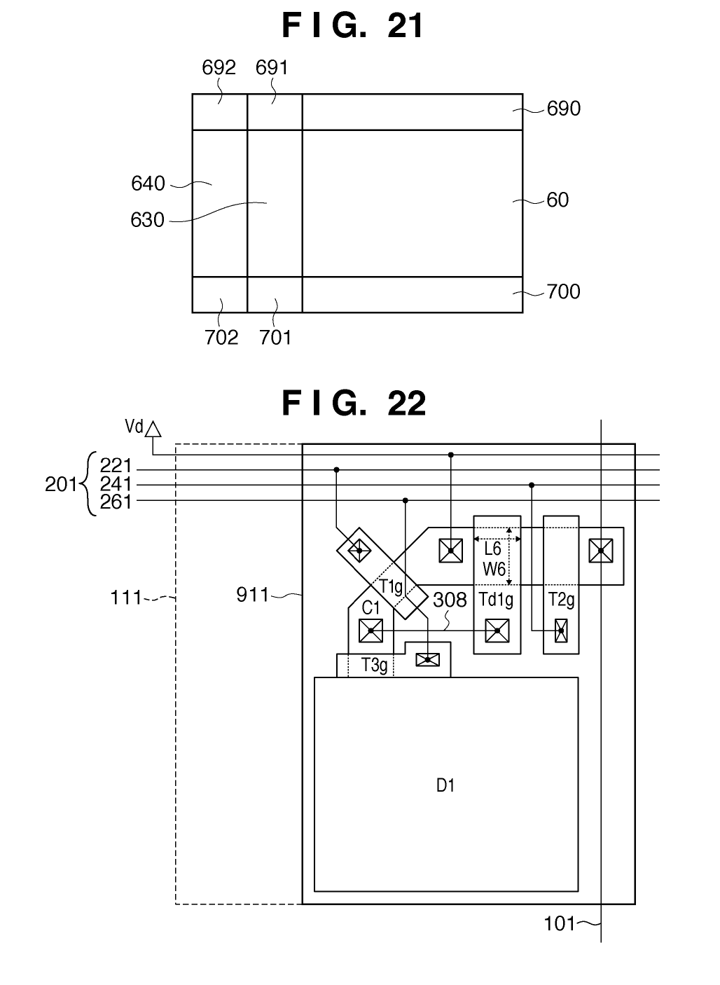

FIG. 21 is a view showing a modification of the pixel array in FIG. 19. The photosensitive pixels 110 having photo-electric conversion elements are arrayed in the effective pixel region 60. Light-shielded pixels are arrayed in OB regions 630, 640, 690, 691, 692, 700, 701, and 702.

As is apparent from the first to third embodiments, the first, second, third, and fourth light-shielded pixels 910, 920, 930, and 940 reduce noise generated by the driving transistor Td1 more effectively than the photosensitive pixel 110 regardless of which of them are arrayed in the OB regions 630, 640, 690, 691, 692, 700, 701, and 702.

In FIG. 21, the ninth and 10th OB regions 69 and 70 serving as the VOB region in the pixel array of FIG. 19 are divided into the OB regions 690, 691, 692, 700, 701, and 702 in accordance with the HOB region width. The OB regions 630, 640, 690, and 700 operate similarly to the first HOB region, second HOB region, fourth VOB region, and fifth VOB region, respectively. In contrast, the OB regions 691, 692, 701, and 702 may be used for either or both of HOB and VOB.

### Sixth Embodiment

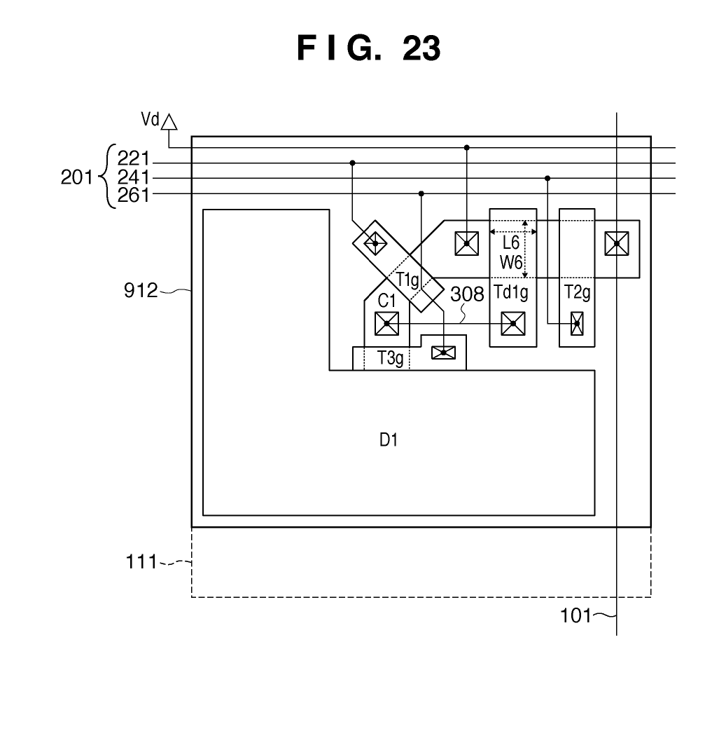

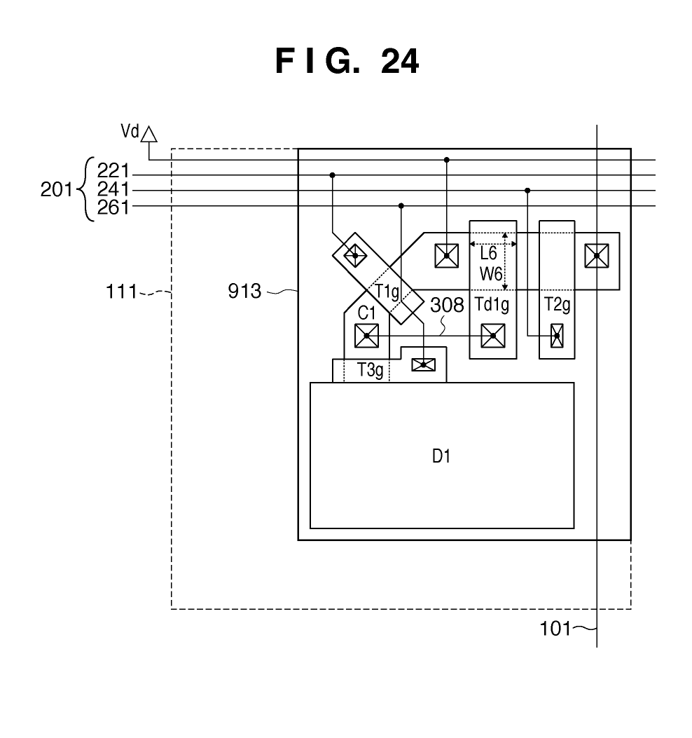

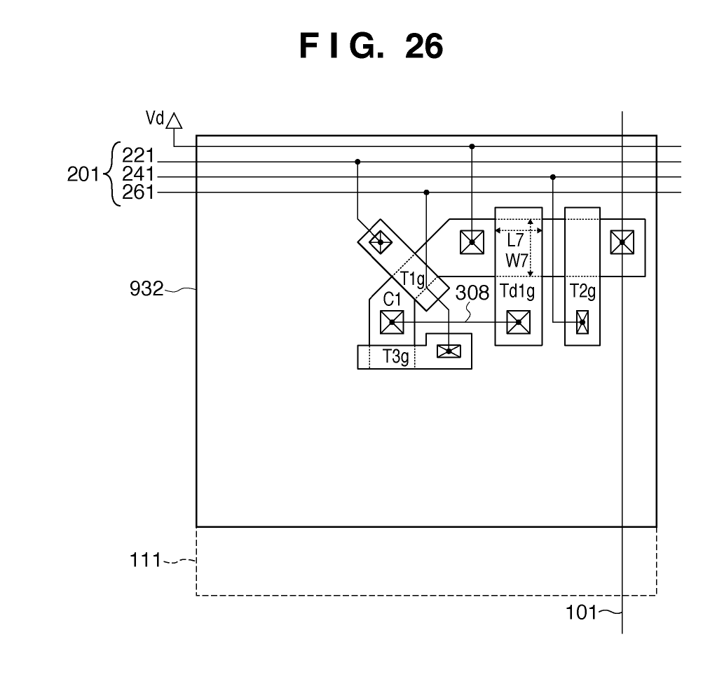

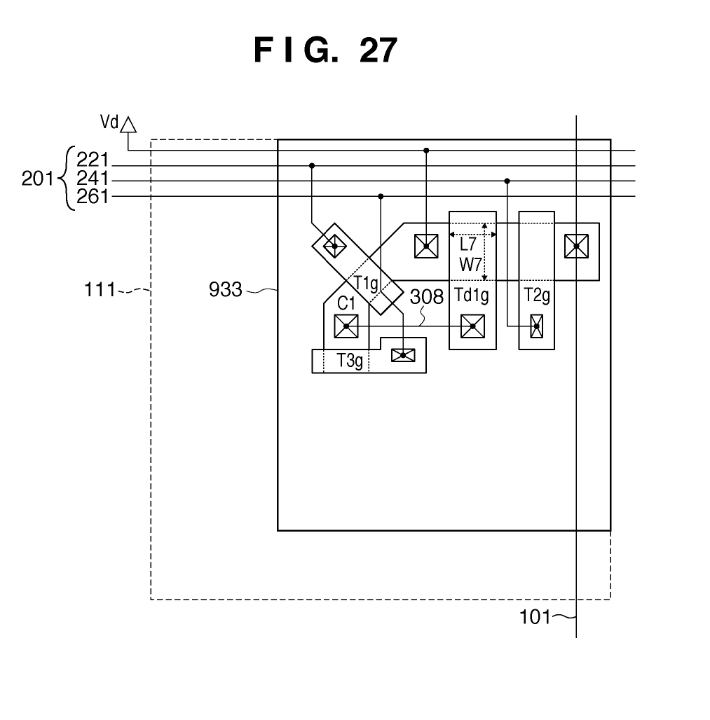

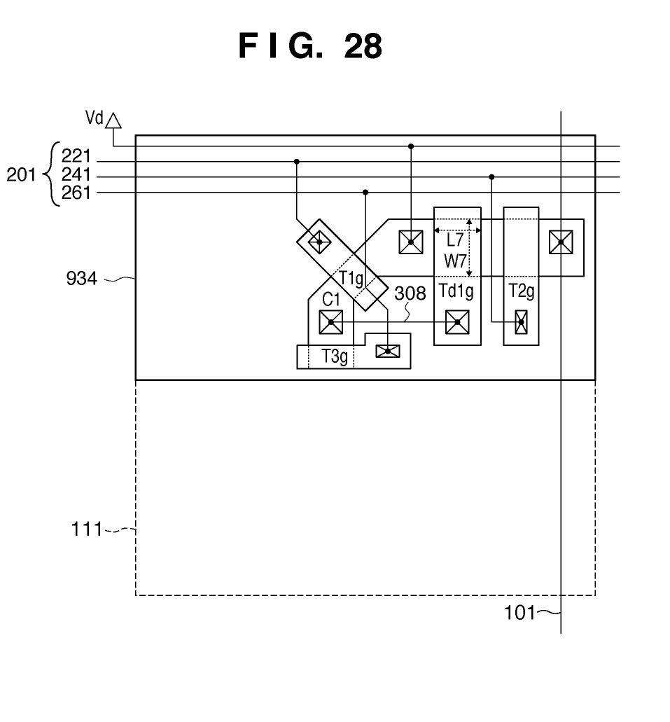

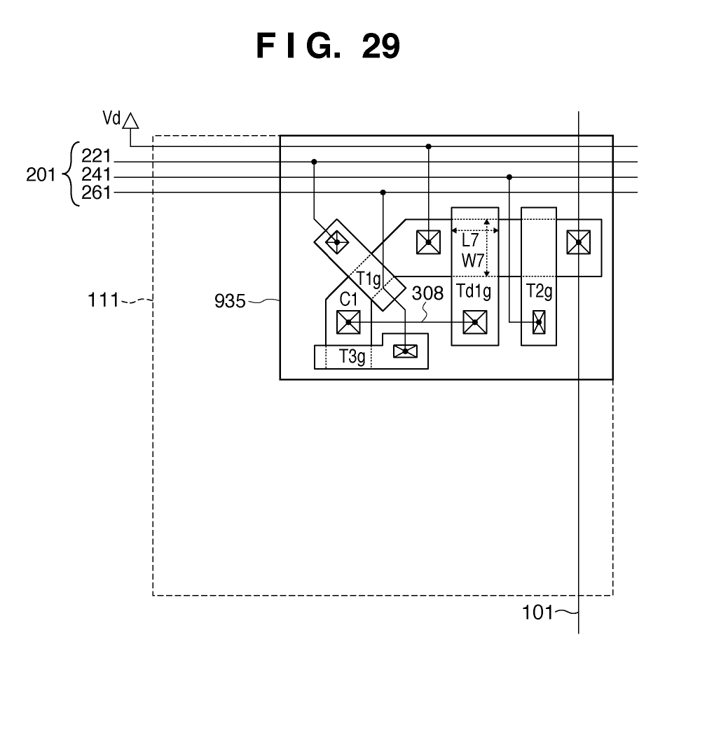

An image capturing apparatus according to the sixth embodiment of the present invention will be explained with reference to FIGS. 22 to 29 in addition to FIGS. 1 to 21. In the sixth embodiment, the basic arrangement and operation of the image capturing apparatus and those of an image sensor are the same as those in the first to fifth embodiments. The sixth embodiment will be explained by applying the same drawings and reference numerals as those in the first to fifth embodiments.

FIGS. 22 to 24 are views showing modifications of the layout of a light-shielded pixel having a photo-electric conversion element. The same reference numerals and symbols as those of a first light-shielded pixel 910 in FIG. 9 denote the same parts. Although the pixel is shielded from light, a light-shielding means 801 is not illustrated. The light-shielded pixel has the same section as that in FIG. 7.

Light-shielded pixels 911, 912, and 913 have photo-electric conversion elements. A dotted line 111 indicates the size of a photosensitive pixel 110 for comparison. A driving transistor Td1 has a gate width (channel width) W6 and a gate length (channel length) L6.

The light-shielded pixel 911 is downsized in the horizontal direction of the pixel by reducing the dimension of the photo-electric conversion element D1 in the horizontal direction. The light-shielded pixel 912 is downsized in the vertical direction of the pixel by reducing the dimension of the photo-electric conversion element D1 in the vertical direction. The light-shielded pixel 913 is downsized in the horizontal and vertical directions of the pixel by reducing the dimensions of the photo-electric conversion element D1 in the horizontal and vertical directions. Since the light-shielded pixels 911, 912, and 913 need not be sensitive to light, reducing the area of the photo-electric conversion element D1 hardly affects a readout reference signal for black level.

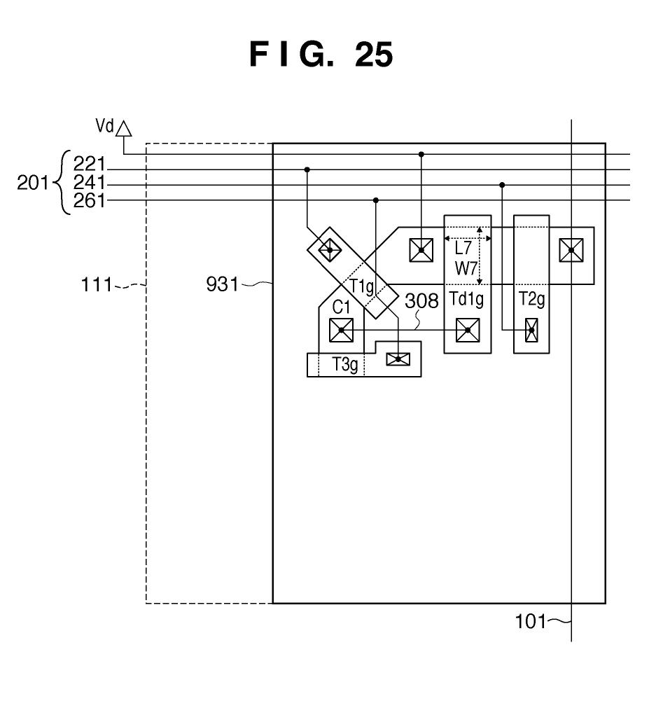

FIGS. 25 to 29 are views showing modifications of the layout of a light-shielded pixel having no photo-electric conversion element. The same reference numerals and symbols as those of a third light-shielded pixel 930 in FIG. 12 denote the same parts. Although the pixel is shielded from light, the light-shielding means 801 is not illustrated. The light-shielded pixel has the same section as that in FIG. 7 except that it does not include the photo-electric conversion element D1 represented by a region 301 in FIG. 7.

Light-shielded pixels 931, 932, 933, 934, and 935 do not have photo-electric conversion elements. The dotted line 111 indicates the size of the photosensitive pixel 110 for comparison. The driving transistor Td1 has a gate width (channel width) W7 and a gate length (channel length) L7.

The light-shielded pixel 931 is downsized in the horizontal direction of the pixel to be equal in size to the light-shielded pixel 911. The light-shielded pixel 932 is downsized in the vertical direction of the pixel to be equal in size to the light-shielded pixel 912. The light-shielded pixel 933 is downsized in the horizontal and vertical directions of the pixel to be equal in size to the light-shielded pixel 913. The light-shielded pixel 934 is downsized in the vertical direction of the pixel more than the light-shielded pixel 932. The light-shielded pixel 935 is downsized in the vertical direction of the pixel more than the light-shielded pixel 933.

Because of the absence of the photo-electric conversion element D1, the light-shielded pixels 931, 932, 933, 934, and 935 are free from the influence of a dark current generated in the photo-electric conversion element D1. Noise in a readout reference signal for black level becomes much smaller than that generated by first and second light-shielded pixels 910 and 920.

A case in which these light-shielded pixels are applied to the pixel arrays shown in FIGS. 5 and 14 to 21 will be explained.

(1) Case in which Light-Shielded Pixels 911 or 931 are Arrayed in HOB Region and Light-Shielded Pixels 910 or 930 are Arrayed in VOB Region

As is apparent from the first to third embodiments, the light-shielded pixel 911 or 931 reduces noise generated by the driving transistor Td1 more effectively than the photosensitive pixel 110. In addition, the horizontal dimension of the light-shielded pixel 911 or 931 is smaller than that of the photosensitive pixel 110. For the same area, the number of light-shielded pixels can be increased, further effectively reducing noise. If the number of light-shielded pixels need not be increased, the area of the HOB region can be reduced, resulting in low manufacturing cost.

In a region common to the HOB and VOB regions, as shown in FIGS. 17, 18, and 21, the light-shielded pixels 911 or 931 suffice to be arrayed. When the light-shielded pixels 911 are arrayed in the HOB region and the light-shielded pixels 910 are arrayed in the VOB region, the light-shielded pixels 911 are arrayed in the common region. When the light-shielded pixels 911 are arrayed in the HOB region and the light-shielded pixels 930 are arrayed in the VOB region, the light-shielded pixels 931 are arrayed in the common region. When the light-shielded pixels 931 are arrayed in the HOB region, they are arrayed in the common region. This arrangement can improve the connection of pixel structures between the respective OB regions. Noise can therefore be removed without affecting the characteristics of the photosensitive pixels 110 in the effective pixel region 60.

(2) Case in which Light-Shielded Pixels 910 or 930 are Arrayed in HOB Region and Light-Shielded Pixels 912, 932, or 934 are Arrayed in VOB Region

The first to third embodiments have clarified that these light-shielded pixels reduce noise generated by the driving transistor Td1 more effectively than the photosensitive pixel 110. Additionally, the vertical dimension of the light-shielded pixel 912, 932, or 934 is smaller than that of the photosensitive pixel 110. For the same area, the number of light-shielded pixels can be increased, further effectively reducing noise. If the number of light-shielded pixels need not be increased, the area of the VOB region can be reduced, decreasing the manufacturing cost.

In a region common to the HOB and VOB regions, as shown in FIGS. 17, 18, and 21, the light-shielded pixels 912, 932, or 934 suffice to be arrayed. When the light-shielded pixels 910 are arrayed in the HOB region and the light-shielded pixels 912 are arrayed in the VOB region, the light-shielded pixels 912 are arrayed in the common region. When the light-shielded pixels 930 are arrayed in the HOB region and the light-shielded pixels 912 are arrayed in the VOB region, the light-shielded pixels 932 are arrayed in the common region. When the light-shielded pixels 932 are arrayed in the VOB region, they are arrayed in the common region. When the light-shielded pixels 934 are arrayed in the VOB region, they are arrayed in the common region. This arrangement can improve the connection of pixel structures between the respective OB regions. As a result, noise can be removed without affecting the characteristics of the photosensitive pixels 110 in the effective pixel region 60.

(3) Case in which Light-Shielded Pixels 911 or 931 are Arrayed in Hob Region and Light-Shielded Pixels 912, 932, or 934 are Arrayed in VOB Region

The first to third embodiments have revealed that these light-shielded pixels reduce noise generated by the driving transistor Td1 more effectively than the photosensitive pixel 110. Further, the horizontal dimension of the light-shielded pixel 911 or 931 is smaller than that of the photosensitive pixel 110. Also, the vertical dimension of the light-shielded pixel 912, 932, or 934 is smaller than that of the photosensitive pixel 110. For the same area, the number of light-shielded pixels can be increased, further effectively reducing noise. If the number of light-shielded pixels need not be increased, the areas of the HOB and VOB regions can be reduced, decreasing the manufacturing cost.

In a region common to the HOB and VOB regions, as shown in FIGS. 17, 18, and 21, the light-shielded pixels 912, 932, or 934 suffice to be arrayed. When the light-shielded pixels 911 are arrayed in the HOB region and the light-shielded pixels 912 are arrayed in the VOB region, the light-shielded pixels 913 are arrayed in the common region. When the light-shielded pixels 931 are arrayed in the HOB region and the light-shielded pixels 912 are arrayed in the VOB region, the light-shielded pixels 933 are arrayed in the common region. When the light-shielded pixels 932 are arrayed in the VOB region, the light-shielded pixels 933 are arrayed in the common region. When the light-shielded pixels 934 are arrayed in the VOB region, the light-shielded pixels 935 are arrayed in the common region. This arrangement can improve the connection of pixel structures between the respective OB regions. Noise can be removed without affecting the characteristics of the photosensitive pixels 110 in the effective pixel region 60.

Applications of the light-shielded pixels 911, 912, 913, 931, 932, 933, 934, and 935 to the pixel array in FIG. 18 based on the above-described concepts will be explained.

### First Array Example

The light-shielded pixels 911 are arrayed in the OB region 630 serving as the first HOB region. The light-shielded pixels 911 are arrayed in the OB region 640 serving as the second HOB region. The light-shielded pixels 912 are arrayed in the OB region 650 serving as the first VOB region. The light-shielded pixels 913 are arrayed in the OB region 651 serving as the first VOB region. The light-shielded pixels 913 are arrayed in the OB region 652 serving as the second HOB region. The light-shielded pixels 912 are arrayed in the OB region 660 serving as the second VOB region. The light-shielded pixels 913 are arrayed in the OB regions 661 and 662 serving as the second VOB regions.

At this time, the conditions of the gate widths (channel widths) W and gate lengths (channel lengths) L of the first and second HOB regions are set to

W of the second HOB region>W of the first HOB region>W1 of the effective pixel region, and

L of the second HOB region>L of the first HOB region>L1 of the effective pixel region

Under these conditions, noise generated by the driving transistor Td1 in the second HOB region can be further reduced, further preventing an HOB clamping correction error sensitive to noise.

Also, the conditions of the gate widths (channel widths) W and gate lengths (channel lengths) L of the first and second VOB regions are set to

W of the first VOB region>W of the second VOB region>W1 of the effective pixel region, and

L of the first VOB region>L of the second VOB region>L1 of the effective pixel region

Under these conditions, noise generated by the driving transistor Td1 in the first VOB region can be further reduced, further preventing a vertical streak noise correction error sensitive to noise.

### Second Array Example

The light-shielded pixels 911 are arrayed in the OB region 630 serving as the first HOB region. The light-shielded pixels 931 are arrayed in the OB region 640 serving as the second HOB region. The light-shielded pixels 912 are arrayed in the OB region 650 serving as the first VOB region. The light-shielded pixels 913 are arrayed in the OB region 651 serving as the first VOB region. The light-shielded pixels 933 are arrayed in the OB region 652 serving as the second HOB region. The light-shielded pixels 932 are arrayed in the OB region 660 serving as the second VOB region. The light-shielded pixels 933 are arrayed in the OB region 661 serving as the second VOB region. The light-shielded pixels 933 are arrayed in the OB region 662 serving as the second VOB region.

Also at this time, the gate widths (channel widths) W and gate lengths (channel lengths) L of the first and second HOB regions are set to have the same conditions as those in the first array example. Under these conditions, an HOB clamping correction error sensitive to noise can be further prevented. The gate widths (channel widths) W and gate lengths (channel lengths) L of the first and second VOB regions are set to have the same conditions as those in the first array example. As a consequence, a vertical streak noise correction error sensitive to noise can be further prevented.

The second HOB region and second VOB region are free from the influence of a dark current generated in the photo-electric conversion element D1 because light-shielded pixels having no photo-electric conversion element D1 are arrayed in these regions. Noise in a readout reference signal for black level therefore becomes much smaller than that generated by light-shielded pixels in the first HOB region and first VOB region.

### Third Array Example

The light-shielded pixels 911 are arrayed in the OB region 630 serving as the first HOB region. The light-shielded pixels 931 are arrayed in the OB region 640 serving as the second HOB region. The light-shielded pixels 932 are arrayed in the OB region 650 serving as the first VOB region. The light-shielded pixels 933 are arrayed in the OB region 651 serving as the first VOB region. The light-shielded pixels 933 are arrayed in the OB region 652 serving as the second HOB region. The light-shielded pixels 934 are arrayed in the OB region 660 serving as the second VOB region. The light-shielded pixels 935 are arrayed in the OB region 661 serving as the second VOB region. The light-shielded pixels 935 are arrayed in the OB region 662 serving as the second VOB region.

Also at this time, the gate widths (channel widths) W and gate lengths (channel lengths) L of the first and second HOB regions are set to have the same conditions as those in the first array example. An HOB clamping correction error sensitive to noise can be further prevented. The gate widths (channel widths) W and gate lengths (channel lengths) L of the first and second VOB regions are set to have the same conditions as those in the first array example. As a result, a vertical streak noise correction error sensitive to noise can be further prevented.

The second HOB region, and first and second VOB regions are free from the influence of a dark current generated in the photo-electric conversion element D1 because light-shielded pixels having no photo-electric conversion element D1 are arrayed in these regions. Noise in a readout reference signal for black level becomes much smaller than that generated by light-shielded pixels in the first HOB region.

The light-shielded pixels 934 and 935 in the second VOB region are smaller in vertical dimension than the light-shielded pixels 932 and 933 in the first VOB region. For the same area, the number of light-shielded pixels can be increased, further effectively reducing noise. If the number of light-shielded pixels need not be increased, the area of the HOB region can be reduced, decreasing the manufacturing cost.

Applications of the light-shielded pixels 911, 912, 913, 931, 932, 933, 934, and 935 to the pixel array in FIG. 21 will be described.

### Fourth Array Example

The light-shielded pixels 911 are arrayed in the OB region 630 serving as the first HOB region. The light-shielded pixels 911 are arrayed in the OB region 640 serving as the second HOB region. The light-shielded pixels 912 are arrayed in the OB region 690 serving as the fourth VOB region. The light-shielded pixels 913 are arrayed in the OB region 691 serving as the fourth VOB region. The light-shielded pixels 913 are arrayed in the OB region 692 serving as the fourth VOB region. The light-shielded pixels 932 are arrayed in the OB region 700 serving as the fifth VOB region. The light-shielded pixels 933 are arrayed in the OB regions 701 and 702 serving as the fifth VOB regions.

Also at this time, the gate widths (channel widths) W and gate lengths (channel lengths) L of the first and second HOB regions are set to have the same conditions as those in the first array example. An HOB clamping correction error sensitive to noise can be further prevented. The conditions of the gate widths (channel widths) W and gate lengths (channel lengths) L of the fourth and fifth VOB regions are set to

W of the fifth VOB region>W of the fourth VOB region>W1 of the effective pixel region, and

L of the fifth VOB region>L of the fourth VOB region>L1 of the effective pixel region

Under these conditions, noise generated by the driving transistor Td1 in the fifth VOB region can be further reduced, further preventing a vertical streak noise correction error sensitive to noise.

The fifth VOB region is free from the influence of a dark current generated in the photo-electric conversion element D1 because light-shielded pixels having no photo-electric conversion element D1 are arrayed in this region. Noise in a readout reference signal for black level therefore becomes much smaller than that generated by light-shielded pixels in the fourth VOB region.

### Fifth Array Example

The light-shielded pixels 911 are arrayed in the OB region 630 serving as the first HOB region. The light-shielded pixels 931 are arrayed in the OB region 640 serving as the second HOB region. The light-shielded pixels 932 are arrayed in the OB region 690 serving as the fourth VOB region. The light-shielded pixels 933 are arrayed in the OB region 691 serving as the fourth VOB region. The light-shielded pixels 933 are arrayed in the OB region 692 serving as the fourth VOB region. The light-shielded pixels 934 are arrayed in the OB region 700 serving as the fifth VOB region. The light-shielded pixels 935 are arrayed in the OB region 701 serving as the fifth VOB region. The light-shielded pixels 935 are arrayed in the OB region 702 serving as the fifth VOB region.

Also at this time, the gate widths (channel widths) W and gate lengths (channel lengths) L of the first and second HOB regions are set to have the same conditions as those in the first array example. An HOB clamping correction error sensitive to noise can therefore be further prevented.

The gate widths (channel widths) W and gate lengths (channel lengths) L of the fourth and fifth VOB regions are set to have the same conditions as those in the fourth array example. A vertical streak noise correction error sensitive to noise can be further prevented.

The second HOB region, and fourth and fifth VOB regions are free from the influence of a dark current generated in the photo-electric conversion element D1 because light-shielded pixels having no photo-electric conversion element D1 are arrayed in these regions. Noise in a readout reference signal for black level thus becomes much smaller than that generated by light-shielded pixels in the first HOB region.

The light-shielded pixels 934 and 935 in the fifth VOB region are smaller in vertical dimension than the light-shielded pixels 932 and 933 in the fourth VOB region. For the same area, the number of light-shielded pixels can be increased, further preventing a vertical streak noise correction error sensitive to noise.

As is apparent from the first to sixth embodiments, light-shielded pixels in each embodiment of the present invention can reduce noise generated by the driving transistor Td1, compared to a photosensitive pixel.

In the fourth, fifth, and sixth embodiments, the number of HOB regions is one or two. However, the gate width (channel width) W and gate length (channel length) L of the driving transistor Td1 of a light-shielded pixel or the horizontal dimension of a light-shielded pixel may be changed in three or more HOB regions.

In the fourth, fifth, and sixth embodiments, the number of VOB regions is one or two. However, the gate width (channel width) W and gate length (channel length) L of the driving transistor Td1 of a light-shielded pixel or the vertical dimension of a light-shielded pixel may be changed in three or more VOB regions.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-063238, filed Mar. 16, 2009, which is hereby incorporated by reference herein in its entirety.

What is claimed is:

1. An image sensor comprising:
an effective pixel having a photo-electric conversion unit for converting an optical signal into charges, a charge-voltage conversion unit for converting a charge into a voltage, and a pixel amplifier for amplifying a voltage of the charge-voltage conversion unit; and
a reference pixel for black level which has a charge-voltage conversion unit and a pixel amplifier and is shielded from light,
wherein each of the pixel amplifier of said effective pixel and the pixel amplifier of said reference pixel for black level has at least one transistor which is connected to the corresponding charge-voltage conversion unit to form a source follower circuit, and said effective pixel and said reference pixel for black level are different in at least one of a gate width and gate length of the transistor of the pixel amplifier.

2. The sensor according to claim 1, wherein the gate width of the transistor of the pixel amplifier of said reference pixel for black level is larger than the gate width of the transistor of the pixel amplifier of said effective pixel.

3. The sensor according to claim 1, wherein the gate length of the transistor of the pixel amplifier of said reference pixel for black level is larger than the gate length of the transistor of the pixel amplifier of said effective pixel.

4. The sensor according to claim 1, wherein said reference pixel for black level includes a reset transistor for resetting the charge-voltage conversion unit.

5. The sensor according to claim 1, wherein said reference pixel for black level does not include a photo-electric conversion unit.

6. The sensor according to claim 1, wherein said reference pixel for black level includes a transfer transistor for controlling transfer of a charge from the photo-electric conversion unit to the charge-voltage conversion unit.

7. The sensor according to claim 6, wherein said effective pixel includes a transfer transistor for controlling transfer of a charge from the photo-electric conversion unit to the charge-voltage conversion unit, and said reference pixel for black level includes the transfer transistor.

8. The sensor according to claim 1, wherein said reference pixel for black level includes a first reference pixel for black level and a second reference pixel for black level different from said first reference pixel for black level.

9. The sensor according to claim 8, wherein the gate width of the transistor of the pixel amplifier of said second reference pixel for black level is larger than the gate width of the transistor of the pixel amplifier of said effective pixel, or the gate length of the transistor of the pixel amplifier of said second reference pixel for black level is larger than the gate length of the transistor of the pixel amplifier of said effective pixel.

10. The sensor according to claim 8, wherein the gate width of the transistor of the pixel amplifier of said second reference pixel for black level is larger than the gate width of the transistor of the pixel amplifier of said first reference pixel for black level, or the gate length of the transistor of the pixel amplifier of said second reference pixel for black level is larger than the gate length of the transistor of the pixel amplifier of said first reference pixel for black level.

11. The sensor according to claim 8, wherein the gate width of the transistor of the pixel amplifier of said first reference pixel for black level is larger than the gate width of the transistor of the pixel amplifier of said effective pixel, or the gate length of the transistor of the pixel amplifier of said first reference pixel for black level is larger than the gate length of the transistor of the pixel amplifier of said effective pixel.

12. The sensor according to claim 8, wherein said second reference pixel for black level includes a reset transistor for resetting the charge-voltage conversion unit.

13. The sensor according to claim 8, wherein said second reference pixel for black level does not include a photo-electric conversion unit.

14. The sensor according to claim 8, wherein said second reference pixel for black level includes a transfer transistor for controlling transfer of a charge from the photo-electric conversion unit to the charge-voltage conversion unit.

15. The sensor according to claim 14, wherein said effective pixel includes a transfer transistor for controlling transfer of a charge from the photo-electric conversion unit to the charge-voltage conversion unit, and said second reference pixel for black level includes the transfer transistor.

16. An image capturing apparatus comprising:
an image sensor including an effective pixel having a photo-electric conversion unit for converting an optical signal into charges, a charge-voltage conversion unit for converting a charge into a voltage, and a pixel amplifier for amplifying a voltage of the charge-voltage conversion unit, and a reference pixel for black level which has a charge-voltage conversion unit and a pixel amplifier and is shielded from light; and
a correction circuit which corrects an image signal output from the effective pixel by using a reference signal for black level output from the reference pixel for black level,
wherein each of the pixel amplifier of the effective pixel and the pixel amplifier of the reference pixel for black level has at least one transistor which is connected to the corresponding charge-voltage conversion unit to form a source follower circuit, and the effective pixel and the reference pixel for black level are different in at least one of a gate width and gate length of the transistor of the pixel amplifier.
